(19) United States
(12) Patent Application Publication
(10) Pub. No.: US 2026/0264370 A1
(43) Pub. Date: Sep. 10, 2026

(54) PREPREG, METAL-CLAD LAMINATE, AND WIRING BOARD

(71) Applicant: PANASONIC INTELLECTUAL PROPERTY MANAGEMENT CO., LTD., Osaka (JP)

(72) Inventor: Daisuke NII, Tokyo (JP)

(73) Assignee: PANASONIC INTELLECTUAL PROPERTY MANAGEMENT CO., LTD., Osaka (JP)

(21) Appl. No.: 19/469,110

(22) PCT Filed: Mar. 22, 2024
(86) PCT No.: PCT/JP2024/011480

§ 371 Date: Sep. 25, 2025

(30) Foreign Application Priority Data
Mar. 30, 2023 (JP) 2023-055776

(51) Int. Cl. B32B 15/14; B32B 5/02; B32B 15/20; C08J 5/24; C08K 3/22; C08K 3/36; C08K 3/40; H05K 1/03

(52) U.S. Cl. CPC B32B 15/14; B32B 5/02; B32B 15/20; C08J 5/248; C08J 5/249; C08K 3/22; C08K 3/36; C08K 3/40; H05K 1/0366; H05K 1/0373; B32B 2260/021; B32B 2260/046; B32B 2307/204; B32B 2307/306; B32B 2457/08; C08J 2325/08; C08J 2371/12; C08K 2003/222; H05K 2201/0141; H05K 2201/0209

(57) ABSTRACT

An aspect of the present invention is a prepreg including a thermosetting composition containing an inorganic filler, which contains at least one selected from the group consisting of silica, quartz glass, and magnesium oxide as a material, at 65 parts by mass or more with respect to 100 parts by mass of a thermosetting compound, which includes at least one selected from the group consisting of a polyphenylene ether compound having a carbon-carbon unsaturated double bond in a molecule, a hydrocarbon-based compound having a carbon-carbon unsaturated double bond in a molecule, and a thermosetting compound having a fluorine atom in a molecule, or a semi-cured product of the thermosetting composition; and a fibrous base material containing a liquid crystal polymer fiber, in which the abundance ratio of the respective groups, as measured by X-ray photoelectron spectroscopy, is in a predetermined relation on the surface of the fibrous base material.

### TECHNICAL FIELD

The present invention relates to a prepreg, a metal-clad laminate, and a wiring board.

### BACKGROUND ART

As the information processing quantity by various kinds of electronic equipment increases, mounting technologies such as high integration of semiconductor devices to be mounted, densification of wiring, and multilayering are progressing. In addition, wiring boards used in various kinds of electronic equipment are required to be, for example, high-frequency compatible wiring boards such as a millimeter-wave radar board for in-vehicle use. Substrate materials for forming insulating layers of wiring boards used in various kinds of electronic equipment are required to be excellent in dielectric properties such as a low relative dielectric constant and a low dielectric loss tangent in order to increase the signal transmission speed and to decrease the signal transmission loss. As such substrate materials, materials, which contain a resin component having a low relative dielectric constant and a low dielectric loss tangent, and further contain not only the resin component but also a fibrous base material such as glass cloth, are sometimes used. As the fibrous base material, glass cloth is often used, but it is also studied to use base materials containing fibers other than glass cloth. As the fibrous base material, examples of a material obtained using a base material containing fibers other than glass cloth include a fiber-reinforced resin composite material described in Patent Literature 1. Examples of the fibrous base material contained in the substrate material include surface-modified wholly aromatic polyester fibers described in Patent Literature 2.

Patent Literature 1 describes a fiber-reinforced resin composite material in which the surface of an aromatic polyester fiber is subjected to plasma etching and treatment with aminopolyamide in a fiber-reinforced resin composite material obtained by containing the aromatic polyester fiber in a heat resistant resin. Patent Literature 1 discloses that a composite material can be obtained which exhibits excellent heat resistance, is excellent in interfacial adhesive properties and therefore sufficiently withstand drilling, and can be effectively used as a printed wiring board material or the like.

Patent Literature 2 describes a surface-modified wholly aromatic polyester fiber, which contains a wholly aromatic polyester polymer and has a proportion of the number of oxygen atoms to the number of carbon atoms on the fiber surface of 30% to 60%. Patent Literature 2 discloses that a surface-modified wholly aromatic polyester fiber can be obtained which is excellent in fiber strength and excellent in interfacial adhesive properties with a matrix resin and can be preferably used for circuit boards and the like.

In electronic equipment, particularly small portable devices such as portable communication terminals and notebook computers, diversification, improvement in performance, thinning, and miniaturization have rapidly proceeded. Along with this, in wiring boards used in these products as well, there is a further demand for refinement of conductor wiring, multilayering of conductor wiring layers, thinning, and improvement in performance such as mechanical properties. For this reason, the insulating layers of wiring boards used in various kinds of electronic equipment are required to have less occurrence of defects even when subjected to drilling using a drill, a laser or the like to form through holes, via holes, and the like. Specifically, a substrate material for forming an insulating layer of a wiring board is required to afford an insulating layer in which peeling is less likely to occur between the wiring and the insulating layer when cut and peeling is less likely to occur between the resin component contained in the insulating layer and the fibrous base material. Hence, the insulating layer of the wiring board is required to exhibit excellent processability so as to sufficiently suppress defects that may occur during processing such as drilling.

Wiring boards used in various kinds of electronic equipment are also required to be hardly affected by changes in the external environment. For example, the wiring boards are also required to be excellent in heat resistance so that the wiring boards can also be used in environments having relatively high temperatures. Hence, substrate materials for forming insulating layers of the wiring boards are required to afford cured products exhibiting excellent heat resistance.

In a case where a conventional base material containing fibers other than glass cloth is used as the fibrous base material, there is a concern that the heat resistance and processability may be insufficient, for example, in a case where the fiber-reinforced resin composite material described in Patent Literature 1 is used and a case where a base material containing the surface-modified wholly aromatic polyester fiber described in Patent Literature 2 is used. Specifically, in a case where the fiber-reinforced resin composite material described in Patent Literature 1 is used, the heat resistance is insufficient. In Patent Literature 1, the interfacial adhesive properties in a case where a polyimide resin and an epoxy resin are used as the heat resistant resin containing the aromatic polyester fiber are studied, but the interfacial adhesive properties in a case where resins other than these are used are not particularly studied. Hence, in the fiber-reinforced resin composite material described in Patent Literature 1, there is a concern that the interfacial adhesive properties may be insufficient and the processability may be insufficient. In Patent Literature 2, heat resistance is not particularly studied, and there is a concern that the material in which a resin is contained in the surface-modified wholly aromatic polyester fiber described in Patent Literature 2 may be insufficient in heat resistance. In Patent Literature 2, the interfacial shear stress in a case where an epoxy resin is contained is studied, but the interfacial shear stress in a case where resins other than these are used is not particularly studied. Hence, in the material in which a resin is contained in the surface-modified wholly aromatic polyester fiber described in Patent Literature 2, there is a concern that the interfacial adhesive properties may be insufficient and the processability may be insufficient.

For these reasons, substrate materials for forming insulating layers of wiring boards are required to afford cured products that are excellent in heat resistance and processability while maintaining excellent dielectric properties.

### CITATION LIST

### Patent Literatures

Patent Literature 1: JP H2-6538 A
Patent Literature 2: WO 2019/131219 A

### SUMMARY OF INVENTION

The present invention has been made in view of such circumstances, and an object thereof is to provide a prepreg, which affords a cured product that is excellent in heat resistance and processability while maintaining excellent dielectric properties. Another object of the present invention is to provide a metal-clad laminate and a wiring board, which are obtained by using the prepreg.

An aspect of the present invention is a prepreg including a thermosetting composition containing a thermosetting compound and an inorganic filler or a semi-cured product of the thermosetting composition; and a fibrous base material containing a liquid crystal polymer fiber, in which the thermosetting compound includes at least one selected from the group consisting of a polyphenylene ether compound having a carbon-carbon unsaturated double bond in a molecule, a hydrocarbon-based compound having a carbon-carbon unsaturated double bond in a molecule, and a thermosetting compound having a fluorine atom in a molecule, the inorganic filler contains at least one selected from the group consisting of silica, quartz glass, and magnesium oxide as a material, a content of the inorganic filler is 65 parts by mass or more with respect to 100 parts by mass of the thermosetting compound, and a ratio of a total amount of a group represented by the following Formula (3), a group represented by the following Formula (4), and a group represented by the following Formula (5) to a total amount of a group represented by the following Formula (1) and a group represented by the following Formula (2), as measured by X-ray photoelectron spectroscopy, is 0.3 or more and less than 0.55 on a surface of the fibrous base material.

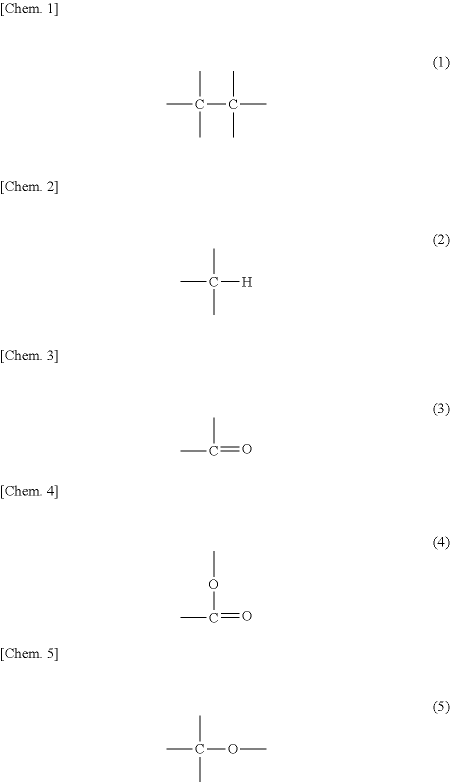

The object described above and other objects, features and advantages of the present invention will become apparent from the following detailed description and accompanying drawings.

### BRIEF DESCRIPTION OF DRAWINGS

FIG. 1 is a schematic sectional view illustrating an example of a prepreg according to an embodiment of the present invention.

FIG. 2 is a schematic sectional view illustrating an example of a metal-clad laminate according to an embodiment of the present invention.

FIG. 3 is a schematic sectional view illustrating an example of a wiring board according to an embodiment of the present invention.

### DESCRIPTION OF EMBODIMENTS

The present inventors have found out that the objects are achieved by the present invention described below as a result of extensive studies.

Hereinafter, embodiments according to the present invention will be described, but the present invention is not limited thereto.

### [Prepreg]

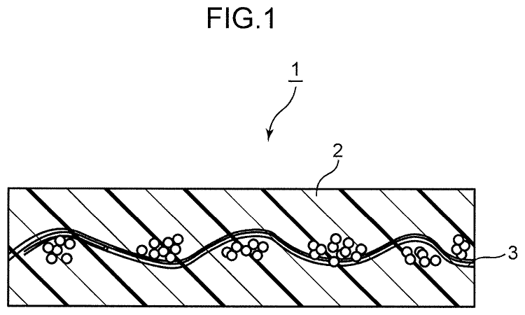

A prepreg according to an embodiment of the present invention includes a thermosetting composition (resin composition) or a semi-cured product of the thermoplastic composition, and a fibrous base material. Examples of this prepreg 1 include a prepreg including a thermosetting composition or a semi-cured product 2 of the thermosetting composition, and a fibrous base material 3 present in the thermosetting composition or the semi-cured product 2 of the thermosetting composition as illustrated in FIG. 1. In the present embodiment, the semi-cured product is the thermosetting composition (resin composition) in a state of being partially cured so as to be further cured. In other words, the semi-cured product is the thermosetting composition in a semi-cured state (B-staged). For example, when a thermosetting composition is heated, the viscosity first gradually decreases as melting proceeds, then curing starts, and the viscosity gradually increases. In such a case, the semi-curing includes a state in which the viscosity has started to gradually decrease but curing is not yet completed, and the like.

The prepreg according to the present embodiment may include a semi-cured product of the thermosetting composition as described above, or may include the uncured thermosetting composition itself. In other words, the prepreg according to the present embodiment may be a prepreg including a semi-cured product of the thermosetting composition (the thermosetting composition in B stage) and a fibrous base material, or a prepreg including the thermosetting composition before being cured (the thermosetting composition in A stage) and a fibrous base material.

The thermosetting composition in the prepreg according to the present embodiment contains a thermosetting compound and an inorganic filler. The thermosetting compound includes at least one selected from the group consisting of a polyphenylene ether compound having a carbon-carbon unsaturated double bond in the molecule, a hydrocarbon-based compound having a carbon-carbon unsaturated double bond in the molecule, and a thermosetting compound having a fluorine atom in the molecule (fluorine-containing thermosetting compound). The inorganic filler contains at least one selected from the group consisting of silica, quartz glass, and magnesium oxide as a material. The content of the inorganic filler is 65 parts by mass or more with respect to 100 parts by mass of the thermosetting compound. In other words, the thermosetting composition is a thermosetting composition containing an inorganic filler, which contains at least one selected from the group consisting of silica, quartz glass, and magnesium oxide as a material, at 65 parts by mass or more with respect to 100 parts by mass of a thermosetting compound, which includes at least one selected from the group consisting of the polyphenylene ether compound, the hydrocarbon-based compound, and the thermosetting compound. The fibrous base material in the prepreg according to the present embodiment is a fibrous base material containing a liquid crystal polymer fiber, in which the ratio (b/a) of the total amount (b) of a group represented by the following Formula (3), a group represented by the following Formula (4), and a group represented by the following Formula (5) to the total amount (a) of a group represented by the following Formula (1) and a group represented by the following Formula (2), as measured by X-ray photoelectron spectroscopy (XPS), is 0.3 or more and less than 0.55 on the surface of the fibrous base material.

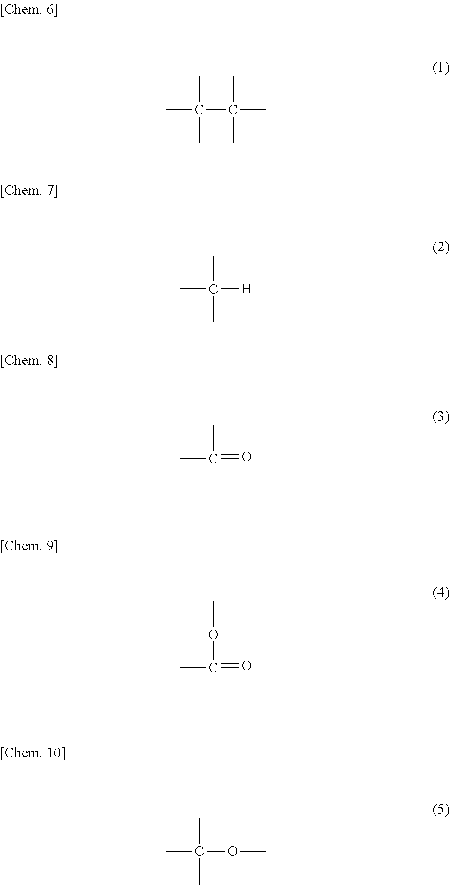

The prepreg affords a cured product that is excellent in heat resistance and processability while maintaining excellent dielectric properties. This is considered to be due to the following. First, when the prepreg is cured, the cured product of the prepreg contains the cured product of the thermosetting composition together with the fibrous base material. The thermosetting composition to be contained in the prepreg (or the thermosetting composition to become a semi-cured product) contains the thermosetting compound including at least one selected from the group consisting of the polyphenylene ether compound, the hydrocarbon-based compound, and the fluorine-containing thermosetting compound. The thermosetting composition constituting the prepreg (or the thermosetting composition to become a semi-cured product) contains the inorganic filler at 65 parts by mass or more with respect to 100 parts by mass of the thermosetting compound, and thus the thermosetting composition contains the inorganic filler in a relatively large amount. From these facts, it is considered that the cured product of the thermosetting composition becomes a cured product that is excellent in heat resistance. Since the inorganic filler is highly filled in the thermosetting composition constituting the prepreg (or the thermosetting composition to become a semi-cured product) as described above, it is considered that the cured product of the thermosetting composition becomes relatively hard (for example, the storage modulus becomes relatively high and the rate of dimensional change due to heating becomes small). In the fibrous base material, the abundance ratio of the respective groups on the surface of the fibrous base material, as measured by X-ray photoelectron spectroscopy, satisfies the above relation. Specifically, the group represented by Formula (3), the group represented by Formula (4), and the group represented by Formula (5) are groups exhibiting higher polarity than the group represented by Formula (1) and the group represented by Formula (2). On the surface of the fibrous base material, groups exhibiting relatively high polarity (higher polarity than the group represented by Formula (1) and the group represented by Formula (2)) such as the group represented by Formula (3), the group represented by Formula (4), and the group represented by Formula (5) are present in certain amounts or more so that the abundance ratio of the respective groups satisfies the above relation. From this fact, regarding the fibrous base material, it is considered that the adhesive properties between the cured product of the thermosetting composition and the fibrous base material are relatively high in the cured product of the prepreg. In other words, on the surface of the fibrous base material, the groups, which exhibit relatively high polarity and are present so that the abundance ratio of the respective groups satisfies the above relation, are considered to suitably contribute to the improvement of adhesive properties between the cured product of the thermosetting composition and the fibrous base material. Hence, the cured product of the prepreg is considered to be a cured product that is excellent in processability so as to sufficiently suppress defects that may occur during processing such as drilling. Specifically, it is considered that peeling is less likely to occur between the cured product of the thermosetting composition and the fibrous base material even when the cured product of the prepreg is cut. In a case where there are a metal layer, wiring and the like on the surface of the cured product of the prepreg (in a metal-clad laminate and wiring board including an insulating layer containing the cured product of the prepreg), it is considered that a defect that may occur, for example, peeling between the metal layer or the wiring and the cured product (the insulating layer) is also suppressed as peeling between the cured product of the thermosetting composition and the fibrous base material is suppressed in the cured product of the prepreg. From this fact as well, it is considered that peeling is less likely to occur between the metal layer or the wiring and the cured product (the insulating layer). From the above, it is considered that according to the prepreg, a prepreg is obtained, which becomes a cured product that is excellent in heat resistance and processability.

In order to suppress loss due to increased resistance accompanying refinement of wiring, the insulating layer equipped in a wiring board is also required to be excellent in dielectric properties, such as a low relative dielectric constant and a low dielectric loss tangent. The cured product of the prepreg is not only excellent in heat resistance and processability, but is also excellent in dielectric properties such as a low relative dielectric constant and a low dielectric loss tangent.

### <Fibrous Base Material>

The fibrous base material in the prepreg according to the present embodiment is a fibrous base material containing a liquid crystal polymer fiber, in which the ratio of the total amount of a group represented by Formula (3), a group represented by Formula (4), and a group represented by Formula (5) to the total amount of a group represented by Formula (1) and a group represented by Formula (2), as measured by X-ray photoelectron spectroscopy, is 0.3 or more and less than 0.55 on the surface of the fibrous base material.

Examples of the liquid crystal polymer fiber include a fiber containing a wholly aromatic polyester polymer. Examples of the liquid crystal polymer fiber (the fiber containing a wholly aromatic polyester polymer) include a fiber obtained by melt spinning a liquid crystalline polyester. The liquid crystalline polyester contains, for example, structural units (repeating units and the like) derived from acids such as an aromatic diol, an aromatic dicarboxylic acid, and an aromatic hydroxycarboxylic acid. The structural units derived from acids such as an aromatic diol, an aromatic dicarboxylic acid, and an aromatic hydroxycarboxylic acid are not particularly limited as long as the effects of the present invention are not impaired. The liquid crystalline polyester may further contain other structural units derived from aromatic diamines, aromatic hydroxyamines, and aromatic aminocarboxylic acids and the like as long as the effects of the present invention are not impaired. As the structural units, structural units represented by the following Formulas (6) to (9) are preferable.

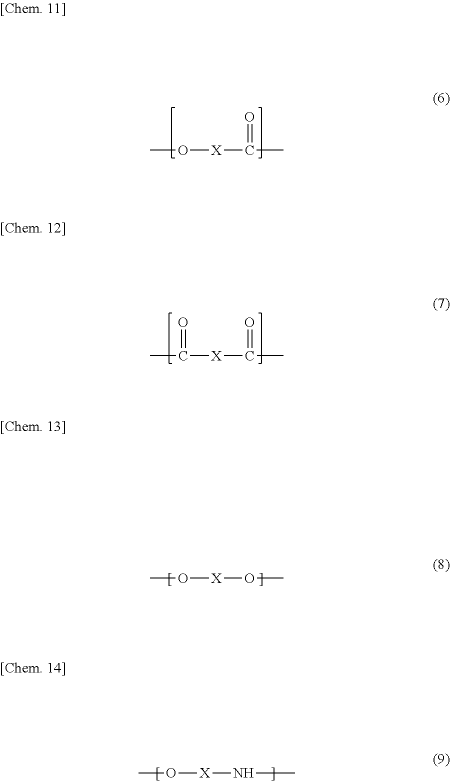

In Formulas (6) to (9), X represents at least one selected from groups represented by Formulas (10) to (17).

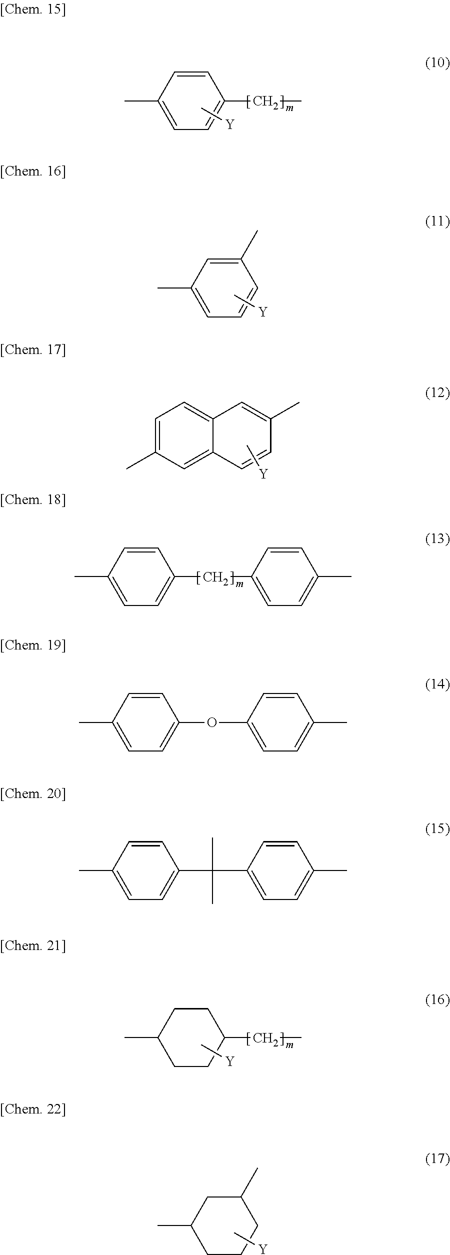

In Formulas (10), (13), and (16), m represents an integer from 0 to 2. In Formulas (10) to (12), (16), and (17), Y represents a hydrogen atom or a substituent of an aromatic ring. In a case where Y is the substituent, the number thereof (number of substituents) is in the range of 1 or more and equal to or less than the maximum number of substituents that can be introduced into the aromatic ring. The substituent represents, for example, a halogen atom, an alkyl group, an alkoxy group, an aryl group, an aralkyl group, an aryloxy group, or an aralkyloxy group. Examples of the halogen atom include a fluorine atom, a chlorine atom, a bromine atom, and an iodine atom. Examples of the alkyl group include an alkyl group having 1 to 4 carbon atoms, and more specific examples thereof include a methyl group, an ethyl group, an isopropyl group, and a t-butyl group. Examples of the alkoxy group include a methoxy group, an ethoxy group, an isopropoxy group, and an n-butoxy group. Examples of the aryl group include a phenyl group and a naphthyl group. Examples of the aralkyl group include a benzyl group (phenylmethyl group) and a phenethyl group (phenylethyl group). Examples of the aryloxy group include a phenoxy group. Examples of the aralkyloxy group include a benzyloxy group.

Examples of the combination of the structural units in the liquid crystalline polyester include combinations of structural units represented by the following Formulas (18) to (34). In a case where a structural unit represented by one formula can take a plurality of structures, the plurality of structural units represented by one formula may be used in combination.

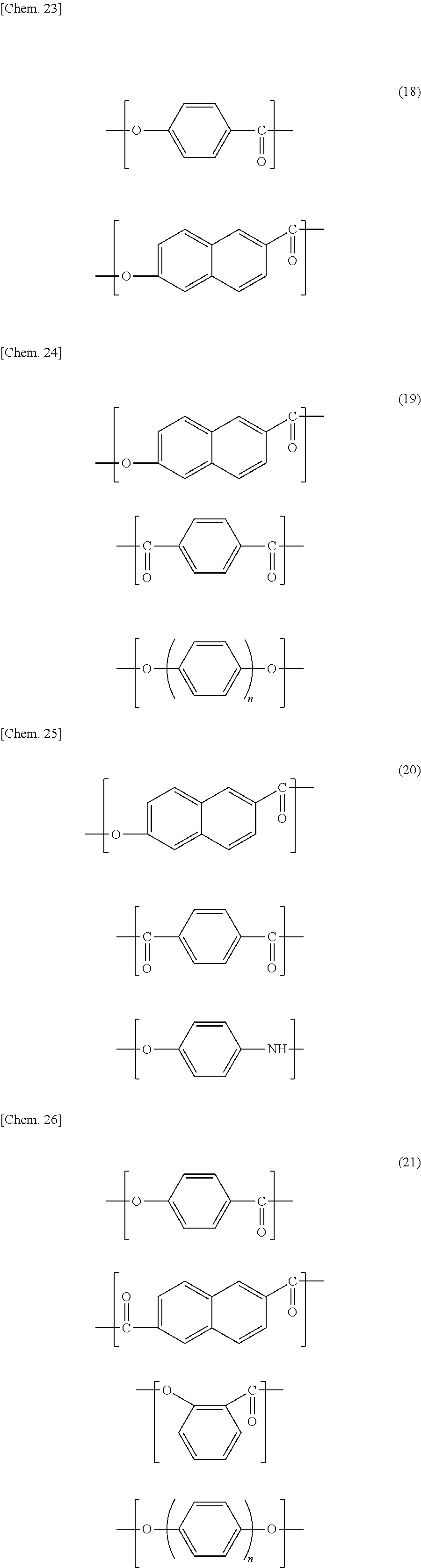

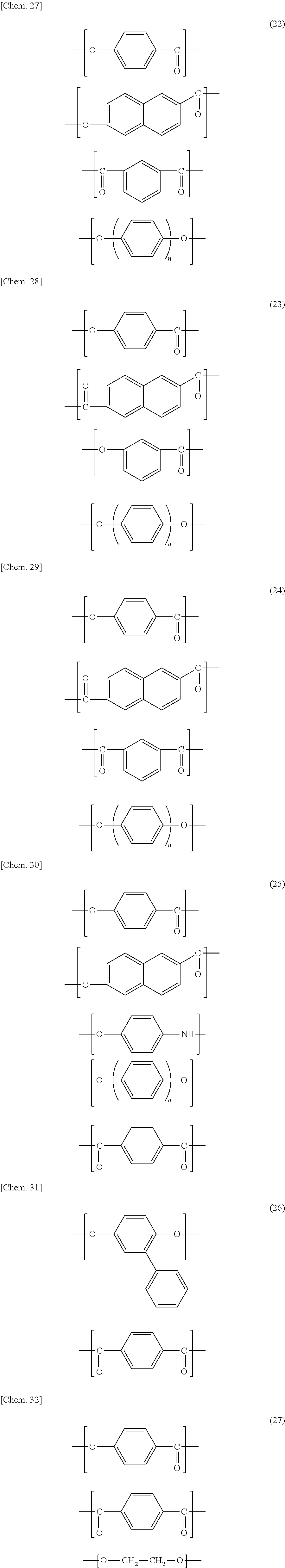

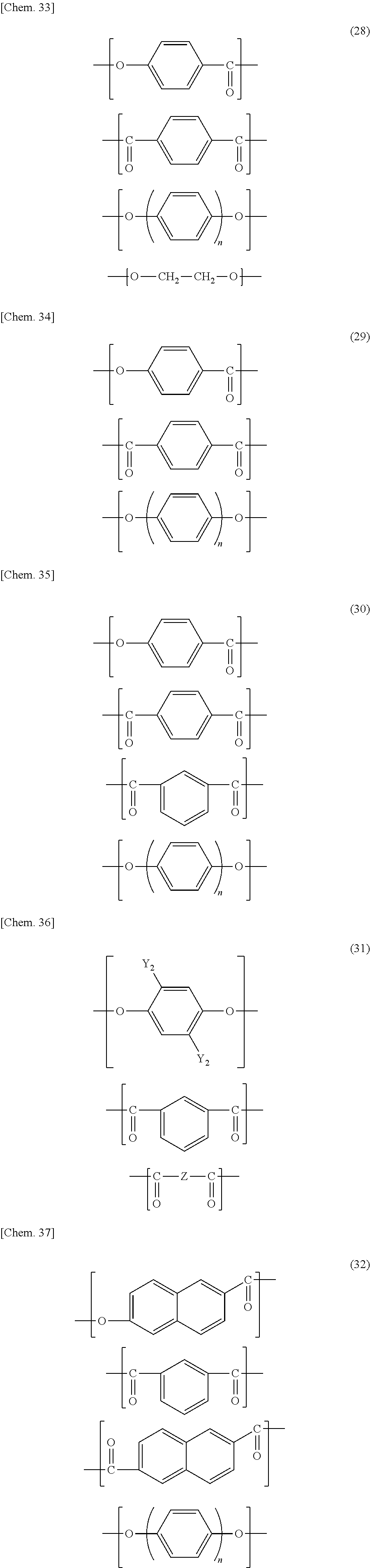

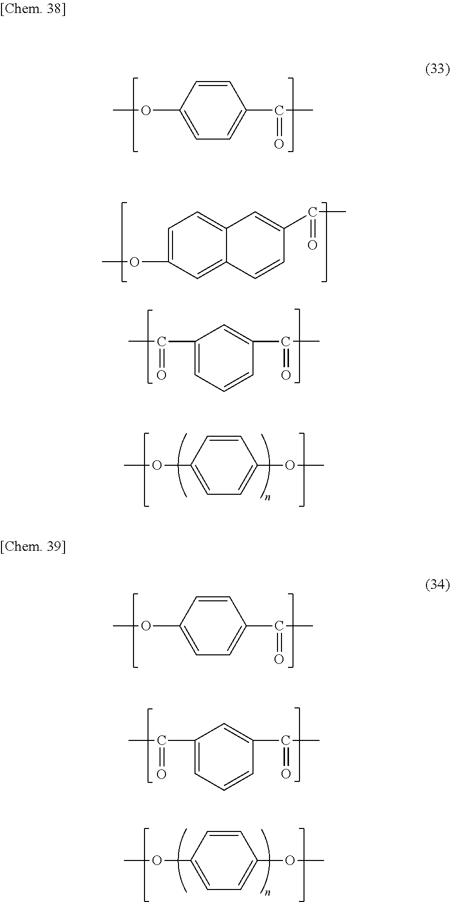

In Formulas (19), (21) to (25), (28) to (30), and (32) to (34), n represents 1 or 2, and a plurality of structural units, which are represented by the same formula but have different numbers of n, may be used concurrently.

In Formula (31), Y₁ and Y₂ each independently represent a hydrogen atom or a substituent. Examples of the substituent include the same groups as those exemplified for Y. Preferred examples of Y₁ and Y₂ include a hydrogen atom, a chlorine atom, a bromine atom, and a methyl group.

In Formula (31), Z represents a group represented by the following Formulas (35) to (39). In other words, Z is at least one selected from the group consisting of groups represented by the following Formulas (35) to (39).

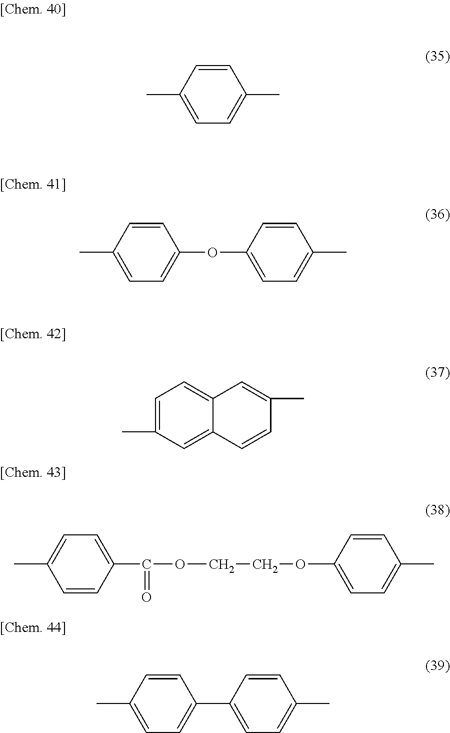

The liquid crystalline polyester preferably contains a naphthalene skeleton as the structural unit, and more preferably contains both a structural unit (A) derived from hydroxybenzoic acid and a structural unit (B) derived from hydroxynaphthoic acid. Examples of the structural unit (A) include a structural unit represented by the following Formula (40). Examples of the structural unit (B) include a structural unit represented by the following Formula (41). The ratio of the structural unit (A) to the structural unit (B) in the liquid crystalline polyester is preferably 9:1 to 1:1, more preferably 7:1 to 1:1, still more preferably 5:1 to 1:1 in terms of molar ratio from the viewpoint of improving melt molding properties. The total amount of the structural unit (A) and the structural unit (B) in the liquid crystalline polyester is preferably 65 mol % or more, more preferably 70 mol % or more, still more preferably 80 mol % or more. It is preferable that the content of the structural unit (A) in the liquid crystalline polyester is 50 to 70 mol % and the content of the structural unit (B) is 4 to 45 mol %.

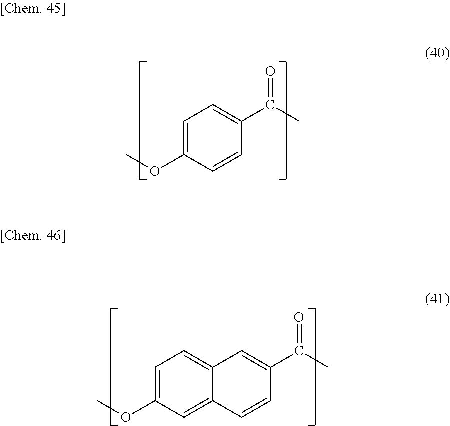

The melting point of the liquid crystalline polyester is not particularly limited, and is preferably, for example, 250° C. to 360° C., more preferably 260° C. to 320° C. The melting point referred to here is the main endothermic peak temperature observed when measured using a differential scanning calorimeter (DSC; “TA3000” manufactured by METTLER TOLEDO) in conformity with the JIS K7121 testing method. In this method, the endothermic peak is measured when 10 to 20 mg of sample is placed in an aluminum pan, nitrogen is allowed to flow as a carrier gas at 100 cc/min, and the temperature is increased at a rate of 20° C./min using the DSC apparatus. Depending on the kind of polymer, a clear peak may not appear in the first temperature increase (1st run) in DSC measurement. In this case, the temperature may be once increased to a temperature 50° C. higher than the expected flow temperature at a rate of 50° C./min, held at that temperature for 3 minutes to ensure complete melting, and then decreased to 50° C. at a rate of −80° C./min, and then the endothermic peak is measured at a rate of temperature increase of 20° C./min.

The liquid crystalline polyester may include other thermoplastic polymers such as polyethylene terephthalate, modified polyethylene terephthalate, polyolefin, polycarbonate, polyamide, polyphenylene sulfide, polyether ether ketone, and fluororesin as long as the effects of the present invention are not impaired. The liquid crystalline polyester may contain various additives such as inorganic substances, colorants such as carbon black, dyes and pigments, antioxidants, ultraviolet absorbers, and light stabilizers. Examples of the inorganic substances include titanium oxide, kaolin, silica, and barium oxide.

As described above, the fibrous base material is a fibrous base material in which the ratio (b/a) of the total amount (b) of a group represented by Formula (3), a group represented by Formula (4), and a group represented by Formula (5) to the total amount (a) of a group represented by Formula (1) and a group represented by Formula (2), as measured by X-ray photoelectron spectroscopy, is 0.3 or more and less than 0.55 on the surface of the fibrous base material. The ratio (b/a) is 0.3 or more and less than 0.55, preferably 0.35 to 0.53, more preferably 0.45 to 0.5. The group represented by Formula (3), the group represented by Formula (4), and the group represented by Formula (5) are groups exhibiting higher polarity than the group represented by Formula (1) and the group represented by Formula (2). From this fact, the ratio (b/a) indicates the ratio of groups exhibiting relatively high polarity to groups exhibiting relatively low polarity on the surface of the fibrous base material. When the ratio (b/a) is within the above range, the fibrous base material is excellent in close contact properties to the cured product of the thermosetting composition. In other words, on the surface of the fibrous base material, the groups, which exhibit relatively high polarity so that the ratio (b/a) is within the above range, are considered to suitably contribute to the improvement of adhesive properties between the cured product of the thermosetting composition and the fibrous base material. Hence, it is considered that peeling is less likely to occur between the cured product of the thermosetting composition and the fibrous base material even when the cured product of the prepreg is cut. In a case where there are a metal layer, wiring and the like on the surface of the cured product of the prepreg (in a metal-clad laminate and wiring board including an insulating layer containing the cured product of the prepreg), it is considered that a defect that may occur, for example, peeling between the metal layer or the wiring and the cured product (the insulating layer) is also suppressed as peeling between the cured product of the thermosetting composition and the fibrous base material is suppressed in the cured product of the prepreg. From this fact as well, it is considered that peeling is less likely to occur between the metal layer or the wiring and the cured product (the insulating layer). Hence, it is considered that a prepreg, which becomes a cured product that is excellent in processability, is obtained.

As the X-ray photoelectron spectroscopy, general X-ray photoelectron spectroscopy can be used for the measurement. The ratio (b/a) can be measured, for example, as follows. The surface of the fibrous base material is subjected to surface X-ray analysis using an X-ray photoelectron spectroscopic analyzer. Thereafter, the spectrum attributed to the carbon peak acquired by this surface X-ray analysis is subjected to peak resolution analysis using predetermined analysis software, and analyzed by calculation using a relative sensitivity factor to calculate the peak area attributed to each bond. The ratio (b/a) is then calculated using this calculated peak area attributed to each bond. Here, when the ratio (b/a) is calculated, the sum of the peak area attributed to the group represented by Formula (1) having a binding energy of 284 eV (that is, a —C—C— bond) and the peak area attributed to the group represented by Formula (2) having a binding energy of 285 eV (that is, a —C—H bond) is used as a. When the ratio (b/a) is calculated, the sum of the peak area attributed to the group represented by Formula (3) having a binding energy of 288 eV (that is, a —C═O bond), the peak area attributed to the group represented by Formula (4) having a binding energy of 289 eV (that is, a —COO bond), and the group represented by Formula (5) having a binding energy of 286 eV (that is, a —C—O— bond) is used as b. Based on these values, the ratio (b/a) measured by XPS can be calculated. The X-ray photoelectron spectroscopic analyzer is not particularly limited as long as it can perform measurement by X-ray photoelectron spectroscopy, and examples thereof include a scanning X-ray photoelectron spectroscopic analyzer (PHI5000 VersaProbe manufactured by ULVAC-PHI, Inc.). In the X-ray photoelectron spectroscopy, a sample can be irradiated with X-rays in a vacuum and measurement can be performed, for example, using a scanning X-ray photoelectron spectroscopic analyzer such as PHI 5000 VersaProbe manufactured by ULVAC-PHI, Inc. The measurement conditions for the surface X-ray analysis are not particularly limited as long as the conditions are conditions in which the ratio (b/a) can be measured, but examples thereof include conditions in which monochromatic Al-Kα rays are used as the X-rays and the X-ray beam diameter is about 100 μmφ (25 W, 15 kV).

Examples of the fibrous base material include a fibrous base material subjected to surface treatment so that the ratio (b/a) is 0.3 or more and less than 0.55 on the surface of the fibrous base material containing a liquid crystal polymer fiber. The surface treatment is not particularly limited as long as it is surface treatment so that the ratio (b/a) becomes 0.3 or more and less than 0.55, and examples thereof include plasma treatment. Examples of the plasma treatment include oxygen gas plasma treatment (surface treatment using plasma generated using oxygen gas as a raw material gas), oxygen and carbon tetrafluoride mixed gas plasma treatment (surface treatment using plasma generated by using a mixed gas of oxygen and carbon tetrafluoride as a raw material gas), and argon, hydrogen and nitrogen mixed gas plasma treatment (surface treatment using plasma generated using a mixed gas of argon, hydrogen, and nitrogen as a raw material gas). In other words, examples of the fibrous base material include a fibrous base material having a surface subjected to plasma treatment, more specific examples thereof include a fibrous base material having a surface subjected to plasma treatment including at least one selected from the group consisting of oxygen gas plasma treatment, oxygen and carbon tetrafluoride mixed gas plasma treatment, and argon, hydrogen and nitrogen mixed gas plasma treatment. By subjecting the surface of the fibrous base material to plasma treatment, a fibrous base material having the ratio (b/a) of 0.3 or more and less than 0.55 is obtained. Hence, by using such a fibrous base material, a prepreg is obtained, which becomes a cured product that is excellent in heat resistance and processability while maintaining excellent dielectric properties. Specifically, by performing plasma treatment, the affinity of the fibrous base material for the resin composition contained (impregnated) in the prepreg is improved, and thus the close contact properties of the fibrous base material to the resin composition are improved. Hence, a prepreg is obtained, which affords a cured product that is excellent in heat resistance and processability while maintaining excellent dielectric properties. As the plasma treatment, among the plasma treatments, the oxygen and carbon tetrafluoride mixed gas plasma treatment is preferable in that this treatment can exert the chemical surface modifying effect in a shorter time than the oxygen gas plasma treatment. As the plasma treatment, among the plasma treatments, the oxygen gas plasma treatment is preferable in that this treatment mainly involves chemical surface modification but not a physical etching effect and is also environmentally friendly. The oxygen and carbon tetrafluoride mixed gas plasma treatment raises concerns about environmental regulations since carbon tetrafluoride has an extremely high global warming potential. The argon, hydrogen and nitrogen mixed gas plasma treatment has a great physical etching effect rather than chemical surface modification. As the plasma treatment, these may be used singly or in combination of two or more kinds thereof.

The conditions for the plasma treatment are not particularly limited as long as the conditions are conditions in which the ratio (b/a) becomes 0.3 or more and less than 0.55. The plasma radiation dose in the plasma treatment is preferably 0.35 to 0.65 W/cm², more preferably 0.45 to 0.55 W/cm² in terms of watt density. The time for which the plasma treatment is performed varies depending on the amount of raw material gas, the plasma density, and the like, but is, for example, preferably 10 to 40 minutes, more preferably 20 to 30 minutes.

The plasma treatment may be treatment using microwave plasma (plasma excited by microwaves), or RF (radio frequency) plasma (plasma excited by RF). The plasma may be pulse excited or DC excited. As the microwave, for example, a microwave having a frequency of 1 GHz or more, which is an industrially usable frequency band and can generate high-density non-equilibrium plasma, can be used, and a microwave having a frequency of 2.45 GHz is preferably used. In the case of the microwave plasma, for example, the microwave power when the plasma atmosphere is generated can be set to, for example, 300 W or more. The RF plasma is plasma that is widely used in industry, and the excitation frequency used to generate the RF plasma is generally 13.56 MHz in Japan from the perspective of legal regulations and the like.

### <Thermosetting Composition>

The thermosetting composition in the prepreg according to the present embodiment contains a thermosetting compound and an inorganic filler as described above. Examples of the thermosetting composition include a thermosetting resin composition containing a thermosetting compound and an inorganic filler, which is used together with a fibrous base material in the prepreg.

### (Thermosetting Compound)

Examples of the thermosetting compound include a polyphenylene ether compound having a carbon-carbon unsaturated double bond in the molecule, a hydrocarbon-based compound having a carbon-carbon unsaturated double bond in the molecule, and a thermosetting compound having a fluorine atom in the molecule (fluorine-containing thermosetting compound) as described above. As the thermosetting compound, these may be used singly or in combination of two or more kinds thereof.

### (Thermosetting Compound: Polyphenylene Ether Compound)

The polyphenylene ether compound is not particularly limited as long as it is a polyphenylene ether compound having a carbon-carbon unsaturated double bond in the molecule. Examples of the polyphenylene ether compound include a polyphenylene ether compound having a carbon-carbon unsaturated double bond at the terminal, and more specific examples thereof include a polyphenylene ether compound having a substituent having a carbon-carbon unsaturated double bond at the molecular terminal, such as a modified polyphenylene ether compound, the end of which is modified with a substituent having a carbon-carbon unsaturated double bond.

Examples of the substituent having a carbon-carbon unsaturated double bond include a group represented by the following Formula (42) and a group represented by the following Formula (43). In other words, examples of the polyphenylene ether compound include a polyphenylene ether compound having at least one selected from a group represented by the following Formula (42) or a group represented by the following Formula (43) in the molecule.

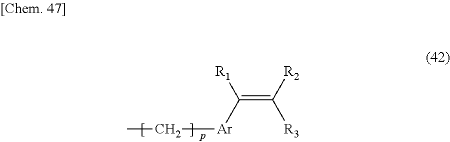

In Formula (42), p represents 0 to 10. Ar represents an arylene group. R₁ to R₃ are independent of each other. In other words, R₁ to R₃ may be the same group as or different groups from each other. R₁ to R₃ represent a hydrogen atom or an alkyl group. In Formula (42), in a case where p is 0, it indicates that Ar is directly bonded to polyphenylene ether.

The arylene group is not particularly limited. Examples of this arylene group include a monocyclic aromatic group such as a phenylene group and a polycyclic aromatic group that is polycyclic aromatic such as a naphthalene ring. This arylene group also includes a derivative in which a hydrogen atom bonded to an aromatic ring is substituted with a functional group such as an alkenyl group, an alkynyl group, a formyl group, an alkylcarbonyl group, an alkenylcarbonyl group, or an alkynylcarbonyl group.

The alkyl group is not particularly limited and is, for example, preferably an alkyl group having 1 to 18 carbon atoms, more preferably an alkyl group having 1 to 10 carbon atoms. Specific examples thereof include a methyl group, an ethyl group, a propyl group, a hexyl group, and a decyl group.

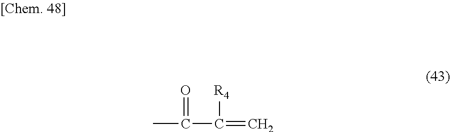

In Formula (43), R₄ represents a hydrogen atom or an alkyl group. The alkyl group is not particularly limited and is, for example, preferably an alkyl group having 1 to 18 carbon atoms, more preferably an alkyl group having 1 to 10 carbon atoms. Specific examples thereof include a methyl group, an ethyl group, a propyl group, a hexyl group, and a decyl group.

Examples of the group represented by Formula (42) include a vinylbenzyl group (ethenylbenzyl group) represented by the following Formula (44). Examples of the group represented by Formula (43) include an acryloyl group and a methacryloyl group.

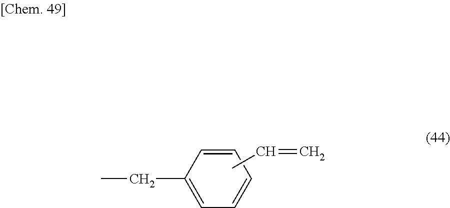

More specific examples of the substituent include vinylbenzyl groups (ethenylbenzyl groups) such as an o-ethenylbenzyl group, a m-ethenylbenzyl group, and a p-ethenylbenzyl group, a vinylphenyl group, an acryloyl group, and a methacryloyl group. The polyphenylene ether compound may have one kind of substituent or two or more kinds of substituents as the substituent. The polyphenylene ether compound may have, for example, any of an o-ethenylbenzyl group, a m-cthenylbenzyl group, or a p-ethenylbenzyl group, or two or three kinds thereof.

The polyphenylene ether compound has a polyphenylene ether chain in the molecule and preferably has, for example, a repeating unit represented by the following Formula (45) in the molecule.

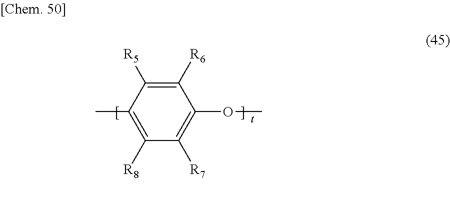

In Formula (45), t represents 1 to 50. R₅ to R₈ are independent of each other. In other words, R₅ to R₈ may be the same group as or different groups from each other. R₅ to R₈ represent a hydrogen atom, an alkyl group, an alkenyl group, an alkynyl group, a formyl group, an alkylcarbonyl group, an alkenylcarbonyl group, or an alkynylcarbonyl group. Among these, a hydrogen atom and an alkyl group are preferable.

Specific examples of the respective functional groups mentioned in R₅ to R₈ include the following.

The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group.

The alkenyl group is not particularly limited and is, for example, preferably an alkenyl group having 2 to 18 carbon atoms and more preferably an alkenyl group having 2 to 10 carbon atoms. Specific examples thereof include a vinyl group, an allyl group, and a 3-butenyl group.

The alkynyl group is not particularly limited and is, for example, preferably an alkynyl group having 2 to 18 carbon atoms and more preferably an alkynyl group having 2 to 10 carbon atoms. Specific examples thereof include an ethynyl group and a prop-2-yn-1-yl group (propargyl group).

The alkylcarbonyl group is not particularly limited as long as it is a carbonyl group substituted with an alkyl group and is, for example, preferably an alkylcarbonyl group having 2 to 18 carbon atoms and more preferably an alkylcarbonyl group having 2 to 10 carbon atoms. Specific examples thereof include an acetyl group, a propionyl group, a butyryl group, an isobutyryl group, a pivaloyl group, a hexanoyl group, an octanoyl group, and a cyclohexylcarbonyl group.

The alkenylcarbonyl group is not particularly limited as long as it is a carbonyl group substituted with an alkenyl group and is, for example, preferably an alkenylcarbonyl group having 3 to 18 carbon atoms and more preferably an alkenylcarbonyl group having 3 to 10 carbon atoms. Specific examples thereof include an acryloyl group, a methacryloyl group, and a crotonoyl group.

The alkynylcarbonyl group is not particularly limited as long as it is a carbonyl group substituted with an alkynyl group and is, for example, preferably an alkynylcarbonyl group having 3 to 18 carbon atoms and more preferably an alkynylcarbonyl group having 3 to 10 carbon atoms. Specific examples thereof include a propioloyl group.

The weight average molecular weight (Mw) and number average molecular weight (Mn) of the polyphenylene ether compound are not particularly limited, and specifically, are preferably 500 to 5,000, more preferably 800 to 4,000, still more preferably 1,000 to 3,000. Here, the weight average molecular weight and number average molecular weight may be those measured by general molecular weight measurement methods, and specific examples thereof include values measured by gel permeation chromatography (GPC). In a case where the polyphenylene ether compound has a repeating unit represented by Formula (45) in the molecule, t is preferably a numerical value so that the weight average molecular weight and number average molecular weight of the polyphenylene ether compound is in such a range. Specifically, t is preferably 1 to 50.

When the weight average molecular weight and number average molecular weight of the polyphenylene ether compound are in the above range, the excellent low dielectric properties of polyphenylene ether are exhibited, and not only the heat resistance of the cured product is superior but also the moldability is excellent. This is considered to be due to the following. When the weight average molecular weight and number average molecular weight of ordinary polyphenylene ether are in the above range, the molecular weight is relatively low, and thus the heat resistance tends to decrease. With regard to this point, it is considered that since the polyphenylene ether compound has one or more unsaturated double bonds at the terminal, a cured product exhibiting sufficiently high heat resistance is obtained as the curing reaction proceeds. When the weight average molecular weight and number average molecular weight of the polyphenylene ether compound are in the above range, it is considered that the molecular weight is relatively low and thus the moldability is also excellent. Hence, it is considered that such a polyphenylene ether compound not only imparts superior heat resistance to the cured product but also exhibits excellent moldability.

In the polyphenylene ether compound, the average number of the substituents (number of terminal functional groups) at the molecular terminal per one molecule of the polyphenylene ether compound is not particularly limited. Specifically, the average number is preferably 1 to 5, more preferably 1 to 3, and still more preferably 1.5 to 3. When the number of terminal functional groups is too small, it tends to be difficult to obtain a cured product exhibiting sufficient heat resistance. When the number of terminal functional groups is too large, the reactivity is too high, and for example, defects such as a deterioration in storage stability of the thermosetting composition and a decrease in fluidity of the thermosetting composition may occur. In other words, when such a polyphenylene ether compound is used, for example, molding defects such as generation of voids at the time of multilayer molding occur by insufficient fluidity and the like and a problem of moldability that a highly reliable printed wiring board is hardly obtained may occur.

The number of terminal functional groups in the polyphenylene ether compound includes a numerical value expressing the average value of the substituents per one molecule of all the polyphenylene ether compounds present in 1 mole of the polyphenylene ether compound. This number of terminal functional groups can be determined by, for example, measuring the number of hydroxyl groups remaining in the obtained polyphenylene ether compound and calculating the number of hydroxyl groups decreased from the number of hydroxyl groups in the polyphenylene ether before having (before being modified with) the substituent. The number of hydroxyl groups decreased from the number of hydroxyl groups in the polyphenylene ether before being modified is the number of terminal functional groups. Moreover, with regard to the method for measuring the number of hydroxyl groups remaining in the polyphenylene ether compound, the number of hydroxyl groups can be determined by adding a quaternary ammonium salt (tetraethylammonium hydroxide) to be associated with a hydroxyl group to a solution of the polyphenylene ether compound and measuring the UV absorbance of the mixed solution.

The intrinsic viscosity of the polyphenylene ether compound is not particularly limited. Specifically, the intrinsic viscosity may be 0.03 to 0.12 dl/g, and is preferably 0.04 to 0.11 dl/g and more preferably 0.06 to 0.095 dl/g. When this intrinsic viscosity is too low, the molecular weight tends to be low, and low dielectric properties such as a low relative dielectric constant and a low dielectric loss tangent tend to be hardly attained. When the intrinsic viscosity is too high, the viscosity is high, sufficient fluidity is not attained, and the moldability of the cured product tends to decrease. Thus, when the intrinsic viscosity of the polyphenylene ether compound is in the above range, excellent heat resistance and moldability of the cured product can be realized.

The intrinsic viscosity here is an intrinsic viscosity measured in methylene chloride at 25° C. and more specifically is, for example, a value attained by measuring the intrinsic viscosity of a methylene chloride solution (liquid temperature: 25° C.) at 0.18 g/45 ml using a viscometer. Examples of the viscometer include AVS500 Visco System manufactured by SCHOTT Instruments GmbH.

Examples of the polyphenylene ether compound include a polyphenylene ether compound represented by the following Formula (46) and a polyphenylene ether compound represented by the following Formula (47). As the polyphenylene ether compound, these polyphenylene ether compounds may be used singly or these two kinds of polyphenylene ether compounds may be used in combination.

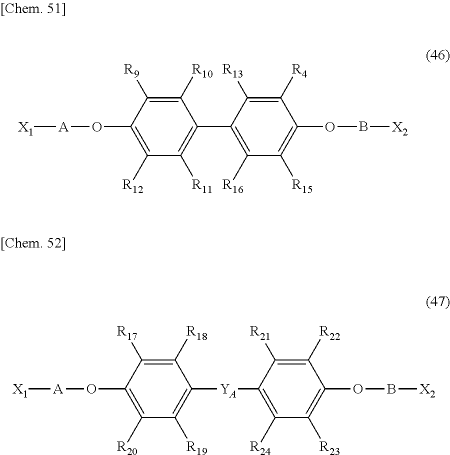

In Formulas (46) and (47), R₉ to R₁₆ and R₁₇ to R₂₄ are independent of each other. In other words, R₉ to R₁₆ and R₁₇ to R₂₄ may be the same group as or different groups from each other. R₉ to R₁₆ and R₁₇ to R₂₄ represent a hydrogen atom, an alkyl group, an alkenyl group, an alkynyl group, a formyl group, an alkylcarbonyl group, an alkenylcarbonyl group, or an alkynylcarbonyl group. X₁ and X₂ are independent of each other. In other words, X₁ and X₂ may be the same group as or different groups from each other. X₁ and X₂ represent a substituent having a carbon-carbon unsaturated double bond. A and B represent a repeating unit represented by the following Formula (48) and a repeating unit represented by the following Formula (49), respectively. In Formula (47), Y_{A} represents a linear, branched, or cyclic hydrocarbon having 20 or less carbon atoms.

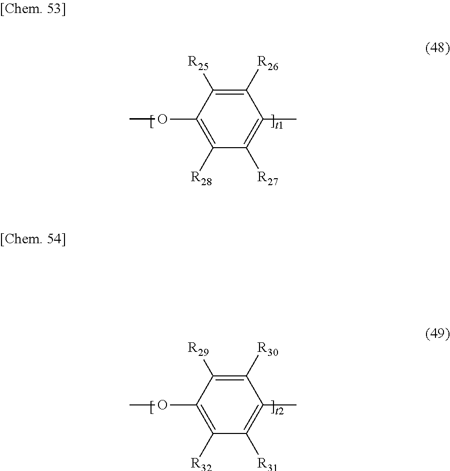

In Formulas (48) and (49), t1 and t2 each represent 0 to 20. R₂₅ to R₂₈ and R₂₉ to R₃₂ are independent of each other. In other words, R₂₅ to R₂₈ and R₂₉ to R₃₂ may be the same group as or different groups from each other. R₂₅ to R₂₈ and R₂₉ to R₃₂ represent a hydrogen atom, an alkyl group, an alkenyl group, an alkynyl group, a formyl group, an alkylcarbonyl group, an alkenylcarbonyl group, or an alkynylcarbonyl group.

The polyphenylene ether compound represented by Formula (46) and the polyphenylene ether compound represented by Formula (47) are not particularly limited as long as they are compounds satisfying the configuration. Specifically, in Formulas (46) and (47), R₉ to R₁₆ and R₁₇ to R₂₄ are independent of each other as described above. In other words, R₉ to R₁₆ and R₁₇ to R₂₄ may be the same group as or different groups from each other. R₉ to R₁₆ and R₁₇ to R₂₄ represent a hydrogen atom, an alkyl group, an alkenyl group, an alkynyl group, a formyl group, an alkylcarbonyl group, an alkenylcarbonyl group, or an alkynylcarbonyl group. Among these, a hydrogen atom and an alkyl group are preferable.

In Formulas (48) and (49), t1 and t2 each preferably represent 0 to 20 as described above. It is preferable that t1 and t2 represent numerical values so that the sum of t1 and t2 is 1 to 30. Hence, it is more preferable that t1 represents 0 to 20, t2 represents 0 to 20, and the sum of t1 and t2 represents 1 to 30. R₂₅ to R₂₈ and R₂₉ to R₃₂ are independent of each other. In other words, R₂₅ to R₂₈ and R₂₉ to R₃₂ may be the same group as or different groups from each other. R₂₅ to R₂₈ and R₂₉ to R₃₂ represent a hydrogen atom, an alkyl group, an alkenyl group, an alkynyl group, a formyl group, an alkylcarbonyl group, an alkenylcarbonyl group, or an alkynylcarbonyl group. Among these, a hydrogen atom and an alkyl group are preferable.

R₉ to R₃₂ are the same as R₅ to R₈ in Formula (45).

In Formula (47), Y_{A} is a linear, branched, or cyclic hydrocarbon having 20 or less carbon atoms as described above. Examples of Y_{A} include a group represented by the following Formula (50).

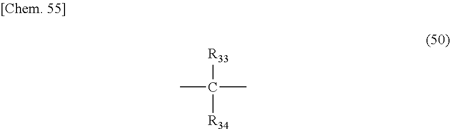

In Formula (50), R₃₃ and R₃₄ each independently represent a hydrogen atom or an alkyl group. Examples of the alkyl group include a methyl group. Examples of the group represented by Formula (50) include a methylene group, a methylmethylene group, and a dimethylmethylene group. Among these, a dimethylmethylene group is preferable.

In Formulas (46) and (47), X₁ and X₂ each independently represent a substituent having a carbon-carbon double bond. In the polyphenylene ether compound represented by Formula (46) and the polyphenylene ether compound represented by Formula (47), X₁ and X₂ may be the same group as or different groups from each other.

More specific examples of the polyphenylene ether compound represented by Formula (46) include a polyphenylene ether compound represented by the following Formula (51).

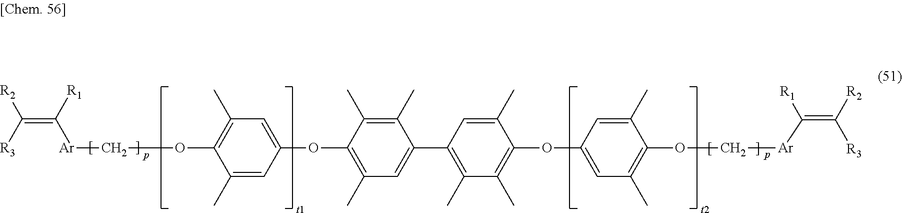

More specific examples of the polyphenylene ether compound represented by Formula (47) include a polyphenylene ether compound represented by the following Formula (52) and a polyphenylene ether compound represented by the following Formula (53).

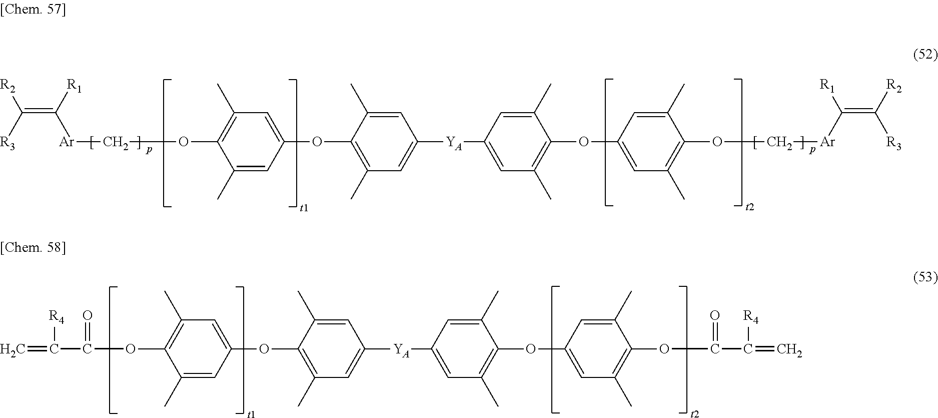

In Formulas (51) to (53), t1 and t2 are the same as t1 and t2 in Formulas (48) and (49). In Formulas (51) and (52), R₁ to R₃, p, and Ar are the same as R₁ to R₃, p, and Ar in Formula (42). In Formulas (52) and (53), Y_{A} is the same as Y_{A} in Formula (47). In Formula (53), R₄ is the same as R₄ in Formula (43).

The method for synthesizing the polyphenylene ether compound used in the present embodiment is not particularly limited as long as a polyphenylene ether compound having a carbon-carbon unsaturated double bond in the molecule can be synthesized. Specific examples of this method include a method in which polyphenylene ether is reacted with a compound in which a substituent having a carbon-carbon unsaturated double bond is bonded to a halogen atom.

Examples of the compound in which a substituent having a carbon-carbon unsaturated double bond is bonded to a halogen atom include compounds in which substituents represented by Formulas (42) to (44) are bonded to a halogen atom. Specific examples of the halogen atom include a chlorine atom, a bromine atom, an iodine atom, and a fluorine atom. Among these, a chlorine atom is preferable. More specific examples of the compound in which a substituent having a carbon-carbon unsaturated double bond is bonded to a halogen atom include o-chloromethylstyrene, p-chloromethylstyrene, and m-chloromethylstyrene. The compound in which a substituent having a carbon-carbon unsaturated double bond is bonded to a halogen atom may be used singly or in combination of two or more kinds thereof. For example, o-chloromethylstyrene, p-chloromethylstyrene, and m-chloromethylstyrene may be used singly or in combination of two or three kinds thereof.

Polyphenylene ether that is a raw material is not particularly limited as long as a predetermined polyphenylene ether compound can be finally synthesized. Specific examples thereof include those containing polyphenylene ether containing 2,6-dimethylphenol and at least one of a bifunctional phenol and a trifunctional phenol and polyphenylene ether such as poly(2,6-dimethyl-1,4-phenylene oxide) as a main component. The bifunctional phenol is a phenol compound having two phenolic hydroxyl groups in the molecule, and examples thereof include tetramethyl bisphenol A. The trifunctional phenol is a phenol compound having three phenolic hydroxyl groups in the molecule.

Examples of the method for synthesizing the polyphenylene ether compound include the methods described above. Specifically, polyphenylene ether as described above and the compound in which a substituent having a carbon-carbon unsaturated double bond is bonded to a halogen atom are dissolved in a solvent and stirred. By doing so, polyphenylene ether reacts with the compound in which a substituent having a carbon-carbon unsaturated double bond is bonded to a halogen atom, and the polyphenylene ether compound used in the present embodiment is obtained.

In the reaction, it is preferable to carry out the reaction in the presence of an alkali metal hydroxide. By doing so, it is considered that this reaction suitably proceeds. This is considered to be because the alkali metal hydroxide functions as a dehydrohalogenating agent, specifically, a dehydrochlorinating agent. In other words, it is considered that the alkali metal hydroxide eliminates the hydrogen halide from the phenol group in polyphenylene ether and the compound in which a substituent having a carbon-carbon unsaturated double bond is bonded to a halogen atom, and by doing so, the substituent having a carbon-carbon unsaturated double bond is bonded to the oxygen atom of the phenol group instead of the hydrogen atom of the phenol group in polyphenylene ether.

The alkali metal hydroxide is not particularly limited as long as it can act as a dehalogenating agent, and examples thereof include sodium hydroxide. The alkali metal hydroxide is usually used in the form of an aqueous solution, specifically, in the form of an aqueous solution of sodium hydroxide.

The reaction conditions such as reaction time and reaction temperature also vary depending on the compound in which a substituent having a carbon-carbon unsaturated double bond is bonded to a halogen atom, and the like, and are not particularly limited as long as they are conditions under which the reaction as described above suitably proceeds. Specifically, the reaction temperature is preferably room temperature to 100° C. and more preferably 30° C. to 100° C. The reaction time is preferably 0.5 to 20 hours, more preferably 0.5 to 10 hours.

The solvent used at the time of the reaction is not particularly limited as long as it can dissolve polyphenylene ether and the compound in which a substituent having a carbon-carbon unsaturated double bond is bonded to a halogen atom, and does not inhibit the reaction of polyphenylene ether with the compound in which a substituent having a carbon-carbon unsaturated double bond is bonded to a halogen atom. Specific examples of the solvent include toluene.

The reaction described above is preferably performed in the presence of not only an alkali metal hydroxide but also a phase-transfer catalyst. In other words, the above reaction is preferably conducted in the presence of an alkali metal hydroxide and a phase transfer catalyst. By doing so, it is considered that the above reaction more suitably proceeds. This is considered to be due to the following. This is considered to be because the phase transfer catalyst is a catalyst which has a function of taking in the alkali metal hydroxide, is soluble in both phases of a phase of a polar solvent such as water and a phase of a non-polar solvent such as an organic solvent, and can transfer between these phases. Specifically, in a case where an aqueous sodium hydroxide solution is used as an alkali metal hydroxide and an organic solvent, such as toluene, which is not compatible with water is used as a solvent, it is considered that even when the aqueous sodium hydroxide solution is dropped into the solvent subjected to the reaction, the solvent and the aqueous sodium hydroxide solution are separated from each other and the sodium hydroxide is hardly transferred to the solvent. In that case, it is considered that the aqueous sodium hydroxide solution added as an alkali metal hydroxide hardly contributes to the promotion of the reaction. In contrast, when the reaction is conducted in the presence of an alkali metal hydroxide and a phase transfer catalyst, it is considered that the alkali metal hydroxide is transferred to the solvent in the state of being taken in the phase transfer catalyst and the aqueous sodium hydroxide solution is likely to contribute to the promotion of the reaction. For this reason, this is considered that the reaction proceeds favorably in the presence of the alkali metal hydroxide and the phase-transfer catalyst.

The phase transfer catalyst is not particularly limited, and examples thereof include quaternary ammonium salts such as tetra-n-butylammonium bromide.

The thermosetting composition used in the present embodiment preferably contains a polyphenylene ether compound obtained as described above as the polyphenylene ether compound.

### (Thermosetting Compound: Hydrocarbon-Based Compound)

The hydrocarbon-based compound is not particularly limited as long as it is a hydrocarbon-based compound having a carbon-carbon unsaturated double bond in the molecule, and examples thereof include a polyfunctional vinyl aromatic compound. As the polyfunctional vinyl aromatic compound, for example, a repeating unit (c) derived from a divinyl aromatic compound and a repeating unit (d) derived from a monovinyl aromatic compound are contained, and a repeating unit (c1) represented by the following Formula (54) is contained as a part of the repeating unit (c) derived from a divinyl aromatic compound.

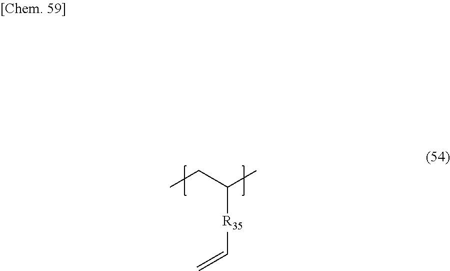

In Formula (54), R₃₃ represents an aromatic hydrocarbon group having 6 to 30 carbon atoms.

In the polyfunctional vinyl aromatic copolymer, the repeating unit (c) is contained at 2 mol % or more and less than 95 mol % and the repeating unit (d) is contained at 5 mol % or more and less than 98 mol % when the sum of the repeating unit (c) and the repeating unit (d) is taken as 100 mol %. The repeating unit (c1) is preferably contained at 2 to 80 mol % when the sum of the repeating unit (c) and the repeating unit (d) is taken as 100 mol %.

It is preferable that the number average molecular weight Mn of the polyfunctional vinyl aromatic copolymer is 300 to 100,000 and the molecular weight distribution (Mw/Mn), which is expressed as the ratio of the weight average molecular weight Mw to the number average molecular weight, is 100.0 or less. The polyfunctional vinyl aromatic copolymer is preferably soluble in toluene, xylene, tetrahydrofuran, dichloroethane or chloroform.

The polyfunctional vinyl aromatic copolymer is not particularly limited, but examples thereof include a copolymer, which is represented by the following Formula (55) and contains the repeating unit (c) derived from a divinyl aromatic compound and the repeating unit (d) derived from a monovinyl aromatic compound. These repeating units may be arranged regularly or randomly.

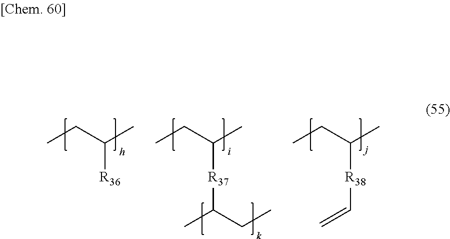

In Formula (55), R₃₆ is an aromatic hydrocarbon group having 6 to 30 carbon atoms, which is derived from a monovinyl aromatic compound, R₃₇ and R₃₈ are each an aromatic hydrocarbon group having 6 to 30 carbon atoms, which is derived from a divinyl aromatic compound. h, i, j, and k are each independently an integer from 0 to 200, provided that the sum of these is 2 to 20,000.

The polyfunctional vinyl aromatic copolymer is preferably a copolymer composed of repeating units in which R₃₆ to R₃₈ in Formula (55) are each independently an aromatic hydrocarbon group selected from the group consisting of a phenyl group, which may have a substituent, a biphenyl group, which may have a substituent, a naphthalene group, which may have a substituent, and a terphenyl group, which may have a substituent.

The polyfunctional vinyl aromatic copolymer is preferably soluble in a solvent. The repeating unit referred to in the present specification is derived from a monomer, and includes units that are present in the main chain of the copolymer and appear repeatedly and units or terminal groups that are present at the terminals or side chains. A repeating unit is also called a structural unit.

The structural unit (c) derived from a divinyl aromatic compound is preferably contained at 2 mol % or more and less than 95 mol % with respect to the total sum of the structural unit (c) derived from a divinyl aromatic compound and the structural unit (d) derived from a monovinyl aromatic compound. The structural unit (c) derived from a divinyl aromatic compound may have a plurality of structures, such as one in which only one of two vinyl groups is reacted and one in which two of two vinyl groups are reacted, but among these, the repeating unit, in which only one vinyl group is reacted, represented by Formula (54) is contained at preferably 2 to 80 mol %, more preferably 5 to 70 mol %, still more preferably 10 to 60%, particularly preferably 15 to 50% with respect to the total sum. As the repeating unit, in which only one vinyl group is reacted, represented by Formula (54) is contained in the above range (for example, 2 to 80 mol %), it is considered that the dielectric loss tangent is low, the heat resistance is excellent, and the compatibility with other resins is excellent. The heat resistance tends to decrease when the content of the repeating unit, in which only one vinyl group is reacted, represented by Formula (54) is too low (for example, less than 2 mol %), and the adhesive strength tends to decrease when the content of the repeating unit, in which only one vinyl group is reacted, represented by Formula (54) is too high (for example, more than 80 mol %).

It is considered that the vinyl group present in Formula (54) acts as a crosslinking component and contributes to exertion of heat resistance of the polyfunctional vinyl aromatic copolymer. Meanwhile, the structural unit (d) derived from a monovinyl aromatic compound does not have a vinyl group since it is considered that the polymerization usually proceeds through the 1,2-addition reaction of a vinyl group. In other words, it is considered that the structural unit (d) derived from a monovinyl aromatic compound does not act as a crosslinking component but contributes to exertion of moldability.

Examples of the monovinyl aromatic compound preferably include styrene. As the monovinyl aromatic compound, a monovinyl aromatic compound other than styrene can also be used together with styrene. In this way, in a case where the structural unit (d) derived from a monovinyl aromatic compound contains a structural unit (d1) derived from styrene and a structural unit (d2) derived from a monovinyl aromatic compound other than styrene, the content of the structural unit (d1) derived from styrene is preferably 99 to 20 mol %, more preferably 98 to 30 mol % when the total sum of the content of the structural unit (d1) derived from styrene and the structural unit (d2) derived from a monovinyl aromatic compound other than styrene is taken as 100 mol %. It is preferable that the content of the structural unit (d1) derived from styrene is in the above range since both resistance to thermal oxidation deterioration and moldability are exhibited. When the content of the structural unit (d1) derived from styrene is too high (for example, more than 99 mol %), the heat resistance tends to decrease. When the content of the structural unit (d2) derived from a monovinyl aromatic compound other than styrene is too high (for example, more than 80 mol %), the moldability tends to decrease.

The number average molecular weight (number average molecular weight in terms of standard polystyrene measured by GPC) of the polyfunctional vinyl aromatic copolymer is preferably 300 to 100,000, more preferably 400 to 50,000, still more preferably 500 to 10,000. When the molecular weight of the polyfunctional vinyl aromatic copolymer is too low (for example, Mn is less than 300), the amount of the monofunctional copolymer component contained in the polyfunctional vinyl aromatic copolymer increases, and so the heat resistance of the cured product tends to decrease. When the molecular weight of the polyfunctional vinyl aromatic copolymer is too high (for example, Mn is more than 100,000), gel is likely to be generated, the viscosity is high, and so molding processability tends to decrease. The value of the molecular weight distribution (Mw/Mn) of the polyfunctional vinyl aromatic copolymer, which is expressed as the ratio of the weight average molecular weight (weight average molecular weight in terms of standard polystyrene measured by GPC) to the Mn, is preferably 100.0 or less, more preferably 50.0 or less, still more preferably 1.5 to 30.0, particularly preferably 2.0 to 20.0. When the molecular weight distribution (Mw/Mn) is too large (for example, Mw/Mn is more than 100.0), the processing characteristics of the polyfunctional vinyl aromatic copolymer (B) tend to be poor, and gel tends to be generated.

The divinyl aromatic compound is considered to play a role in forming a branched structure and making the copolymer polyfunctional as well as play a role as a crosslinking component for exerting heat resistance when the obtained polyfunctional vinyl aromatic copolymer is heat-cured. Examples of the divinyl aromatic compound are not limited as long as they are aromatic compounds having two vinyl groups, but divinylbenzene (including the respective regioisomers or mixtures thereof), divinylnaphthalene (including the respective regioisomers or mixtures thereof), and divinylbiphenyl (including the respective regioisomers or mixtures thereof) are preferably used. These can be used singly or in combination of two or more kinds thereof. As the divinyl aromatic compound, divinylbenzene (m-isomer, p-isomer, or a regioisomer mixture thereof) is more preferable from the viewpoint of molding processability.

Examples of the monovinyl aromatic compound include styrene and a monovinyl aromatic compound other than styrene. As the monovinyl aromatic compound, it is desirable to use, for example, styrene essentially and a monovinyl aromatic compound other than styrene concurrently.

Styrene is considered to play a role in imparting excellent low dielectric properties and resistance to thermal oxidation deterioration to the polyfunctional vinyl aromatic copolymer as a monomer component as well as play a role in controlling the molecular weight of the polyfunctional vinyl aromatic copolymer as a chain transfer agent. The monovinyl aromatic compound other than styrene is considered to improve the solubility in solvent and processability of the polyfunctional vinyl aromatic copolymer.

Examples of the monovinyl aromatic compound other than styrene are not limited as long as they are aromatic compounds having one vinyl group other than styrene, and include vinyl aromatic compounds such as vinylnaphthalene and vinylbiphenyl; and nuclear alkyl-substituted vinyl aromatic compounds such as o-methylstyrene, m-methylstyrene, p-methylstyrene, o,p-dimethylstyrene, o-ethylvinylbenzene, m-ethylvinylbenzene and p-ethylvinylbenzene. The monovinyl aromatic compound other than styrene is preferably ethylvinylbenzene (including the respective regioisomers or mixtures thereof), ethylvinylbiphenyl (including the respective regioisomers or mixtures thereof), or ethylvinylnaphthalene (including the respective regioisomers and mixtures thereof) since the compound prevents gelation of the polyfunctional vinyl aromatic copolymer, is highly effective in improving solubility in solvent and processability, is low in cost, and is readily available. The monovinyl aromatic compound other than styrene is preferably ethylvinylbenzene (m-isomer, p-isomer, or a regioisomer mixture of thereof) from the viewpoint of dielectric properties and cost.

In addition to the divinyl aromatic compound and the monovinyl aromatic compound, structural units (e) derived from one or two or more other monomer components such as a trivinyl aromatic compound, a trivinyl aliphatic compound, a divinyl aliphatic compound, and a monovinyl aliphatic compound can be introduced into the polyfunctional vinyl aromatic copolymer using these compounds as long as the effects of the present invention are not impaired.

Examples of the other monomer components include 1,3,5-trivinylbenzene, 1,3,5-trivinylnaphthalene, 1,2,4-trivinylcyclohexane, ethylene glycol diacrylate, butadiene, 1,4-butanediol divinyl ether, cyclohexanedimethanol divinyl ether, diethylene glycol divinyl ether and triallyl isocyanurate. These can be used singly or in combination of two or more kinds thereof.

The mole fraction of the other monomer components is preferably less than 30 mol % with respect to the total sum of all monomer components. In other words, the molar fraction of the structural units (e) derived from other monomer components is preferably less than 30 mol % with respect to the structural units derived from all monomer components constituting the copolymer [the total sum of the structural unit (c) derived from a divinyl aromatic compound, the structural unit (d) derived from a monovinyl aromatic compound, and the structural units (e) derived from other monomer components].

### (Thermosetting Compound: Fluorine-Containing Thermosetting Compound)

The fluorine-containing thermosetting compound is not particularly limited as long as it is a thermosetting compound having a fluorine atom in the molecule, and examples thereof include a thermosetting resin having a fluorine atom in the molecule. Examples of the fluorine-containing thermosetting compound include a polymer having a unit based on a fluoroolefin and a unit containing a crosslinkable reactive group in the molecule. Examples of the fluoroolefin include an olefin in which one or more hydrogen atoms are substituted with a fluorine atom. Examples of the unit based on a fluoroolefin include a unit obtained by polymerizing the fluoroolefin. Examples of the crosslinkable reactive group include a crosslinkable reactive groups that can react with each other by being heated to cure the fluorine-containing thermosetting compound.

Examples of the fluorine-containing thermosetting compound include a fluororesin having a structure represented by the following Formula (56).

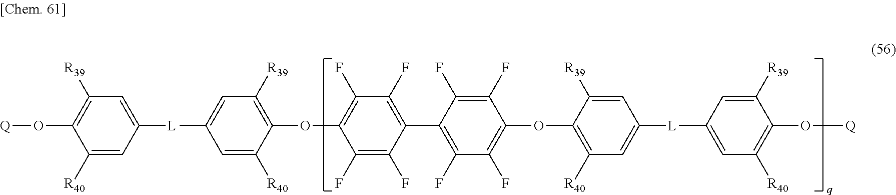

In Formula (56), q represents 1 to 100, L represents a cycloalkylidene group having 5 to 12 carbon atoms, which may have a substituent, R₃₉ and R₄₀ each independently represent at least one selected from the group consisting of a hydrogen atom, a fluorine atom, a saturated or unsaturated hydrocarbon group having 1 to 10 carbon atoms in which some or all of the hydrogen atoms may be substituted with a halogen atom, and an aryl group having 6 to 10 carbon atoms in which some or all of the hydrogen atoms may be substituted with a halogen atom, and Q represents a group containing an olefinic carbon-carbon double bond or carbon-carbon triple bond.

In Formula (56), q is preferably 1 to 100, more preferably 3 to 50, still more preferably 5 to 30. By setting q to be in the above range, sufficient heat resistance, an appropriate glass transition temperature (Tg), and sufficient solubility in solvent can be simultaneously achieved. By setting q to be in the above range, it is possible to adjust the number of the substituents Q contained in unit weight of the resin and achieve appropriate crosslinkability and excellent electrical properties (such as relative dielectric constant and dielectric loss tangent). When a varnish is formed using the fluororesin having a structure represented by Formula (56), it is possible to impart an appropriate viscosity to the varnish by setting q to be in the above range.

In Formula (56), Q is a cycloalkylidene group having 5 to 12 carbon atoms, which may have a substituent. Among these, Q is preferably one selected from the group consisting of a cyclopentylidene group, which may have a substituent, a cyclohexylidene group, which may have a substituent, and a cyclododecylidene group, which may have a substituent. Without wishing to be bound by any theory, it is considered that the cycloalkylidene group contributes to an increase in solubility in solvent as well as a decrease in dielectric constant due to an increase in bulkiness.

The substituent present on the cycloalkylidene group may be a saturated or unsaturated hydrocarbon group having 1 to 10 carbon atoms in which some or all of the hydrogen atoms may be substituted with a halogen atom or an aryl group having 6 to 10 carbon atoms in which some or all of the hydrogen atoms may be substituted with a halogen atom. Examples of the saturated or unsaturated hydrocarbon group having 1 to 10 carbon atoms in which some or all of the hydrogen atoms may be substituted with a halogen atom include a methyl group, an ethyl group, a propyl group, a 2-methylpropyl group (isobutyl group), a butyl group, a pentyl group, a trifluoromethyl group, a pentafluoroethyl group, a perfluoropropyl group, a vinyl group, an allyl group, a 1-methylvinyl group, a 2-butenyl group, and a 3-butenyl group. Examples of the aryl group having 6 to 10 carbon atoms in which some or all of the hydrogen atoms may be substituted with a halogen atom include a phenyl group, a naphthyl group (including a 1-isomer and a 2-isomer), and a perfluorophenyl group.

In formula (56), R₃₉ and R₄₀ may each be independently a hydrogen atom, a fluorine atom, a saturated or unsaturated hydrocarbon group having 1 to 10 carbon atoms in which some or all of the hydrogen atoms may be substituted with a halogen atom, or an aryl group having 6 to 10 carbon atoms in which some or all of the hydrogen atoms may be substituted with a halogen atom. Examples of the saturated or unsaturated hydrocarbon group having 1 to 10 carbon atoms in which some or all of the hydrogen atoms may be substituted with a halogen atom include a methyl group, an ethyl group, a propyl group, a 2-methylpropyl group (isobutyl group), a butyl group, a pentyl group, a trifluoromethyl group, a pentafluoroethyl group, a perfluoropropyl group, a vinyl group, an allyl group, a 1-methylvinyl group, a 2-butenyl group, and a 3-butenyl group. Examples of the aryl group having 6 to 10 carbon atoms in which some or all of the hydrogen atoms may be substituted with a halogen atom include a phenyl group, a naphthyl group (including a 1-isomer and a 2-isomer), and a perfluorophenyl group.

In Formula (56), Q is a group containing an olefinic carbon-carbon double bond or carbon-carbon triple bond. In several aspects, Q is a group containing an olefinic carbon-carbon double bond or carbon-carbon triple bond and at least one fluorine atom. In another aspect, Q is a group that contains an olefinic carbon-carbon double bond or carbon-carbon triple bond but does not contain a fluorine atom.

### (Inorganic Filler)

The inorganic filler is not particularly limited as long as it is a filler containing at least one selected from the group consisting of silica, quartz glass, and magnesium oxide as a material. Examples of the inorganic filler include a filler that can be used as a filler in a thermosetting composition such as a thermosetting resin composition and contains at least one selected from the group consisting of silica, quartz glass, and magnesium oxide as a material. The filler containing silica as a material is not particularly limited, examples thereof include crushed silica, spherical silica, and silica particles, and spherical silica is preferable. The inorganic filler is only required to be a filler containing at least one selected from the group consisting of silica, quartz glass, and magnesium oxide as a material, and may include an inorganic filler other than this (another inorganic filler). Examples of the material of the other inorganic filler include metal oxides other than silica and magnesium oxide, metal hydroxides, molybdates, talc, aluminum borate, barium sulfate, aluminum nitride, boron nitride, barium titanate, strontium titanate, calcium titanate, magnesium carbonate such as anhydrous magnesium carbonate, and calcium carbonate. Examples of the metal oxides other than silica and magnesium oxide include alumina, titanium oxide, magnesium oxide, and mica. Examples of the metal hydroxides include magnesium hydroxide and aluminum hydroxide. Examples of the molybdates include zinc molybdate, calcium molybdate, and magnesium molybdate. The inorganic filler may be used singly or in combination of two or more kinds thereof.

The inorganic filler may be an inorganic filler subjected to surface treatment or an inorganic filler not subjected to surface treatment. Examples of the surface treatment include treatment with a silane coupling agent.

The silane coupling agent is not particularly limited, and examples thereof include a silane coupling agent having at least one functional group selected from the group consisting of a vinyl group, a styryl group, a methacryloyl group, an acryloyl group, a phenylamino group, an isocyanurate group, a ureido group, a mercapto group, an isocyanate group, an epoxy group, and an acid anhydride group. In other words, examples of this silane coupling agent include compounds having at least one of a vinyl group, a styryl group, a methacryloyl group, an acryloyl group, a phenylamino group, an isocyanurate group, a ureido group, a mercapto group, an isocyanate group, an epoxy group, and an acid anhydride group as a reactive functional group, and further a hydrolyzable group such as a methoxy group or an ethoxy group.

Examples of the silane coupling agent include vinyltriethoxysilane and vinyltrimethoxysilane as those having a vinyl group. Examples of the silane coupling agent include p-styryltrimethoxysilane and p-styryltricthoxysilane as those having a styryl group. Examples of the silane coupling agent include 3-methacryloxypropyltrimethoxysilane, 3-methacryloxypropylmethyldimethoxysilane, 3-methacryloxypropyltriethoxysilane, 3-methacryloxypropylmethyldiethoxysilane, and 3-methacryloxypropylethyldiethoxysilane as those having a methacryloyl group. Examples of the silane coupling agent include 3-acryloxypropyltrimethoxysilane and 3-acryloxypropyltriethoxysilane as those having an acryloyl group. Examples of the silane coupling agent include N-phenyl-3-aminopropyltrimethoxysilane and N-phenyl-3-aminopropyltriethoxysilane as those having a phenylamino group.

The average particle size of the inorganic filler is not particularly limited, and is preferably 0.05 to 10 μm, more preferably 0.1 to 8 μm. Here, the average particle size refers to the volume average particle size. The volume average particle size can be measured by, for example, a laser diffraction method and the like.

### (Content)

The content of the inorganic filler is 65 parts by mass or more, preferably 70 to 150 parts by mass, more preferably 80 to 130 parts by mass with respect to 100 parts by mass of the thermosetting compound. The content of the inorganic filler is 45 parts by mass or more, preferably 50 to 107 parts by mass, more preferably 57 to 93 parts by mass with respect to 100 parts by mass of the thermosetting composition. The content of the thermosetting compound is 36 to 96 parts by mass, preferably 50 to 82 parts by mass, more preferably 57 to 75 parts by mass with respect to 100 parts by mass of the thermosetting composition. When the content of the inorganic filler is within the above range, a prepreg is obtained, which becomes a cured product that is excellent in heat resistance and processability while maintaining excellent dielectric properties. This is considered to be due to the following. Since the thermosetting composition contains the inorganic filler in a relatively large amount, it is considered that the cured product of the thermosetting composition is a cured product that is excellent in heat resistance. Since the inorganic filler is highly filled in the thermosetting composition constituting the prepreg (or the thermosetting composition to become a semi-cured product) as described above, it is considered that the cured product of the thermosetting composition becomes relatively hard (for example, the storage modulus becomes relatively high and the rate of dimensional change due to heating becomes small). From this fact, the cured product of the prepreg is considered to be a cured product that is excellent in processability so as to sufficiently suppress defects that may occur during processing such as drilling. Specifically, it is considered that peeling is less likely to occur between the cured product of the thermosetting composition and the fibrous base material even when the cured product of the prepreg is cut. In a case where there are a metal layer, wiring and the like on the surface of the cured product of the prepreg (in a metal-clad laminate and wiring board including an insulating layer containing the cured product of the prepreg), it is considered that a defect that may occur, for example, peeling between the metal layer or the wiring and the cured product (the insulating layer) is also suppressed as peeling between the cured product of the thermosetting composition and the fibrous base material is suppressed in the cured product of the prepreg. From this fact as well, it is considered that peeling is less likely to occur between the metal layer or the wiring and the cured product (the insulating layer). Hence, it is considered that a prepreg is obtained, which becomes a cured product that is excellent in heat resistance and processability while maintaining excellent dielectric properties.

### (Other Components)

The thermosetting composition according to the present embodiment may contain components (other components) other than the thermosetting compound and the inorganic filler, if necessary, as long as the effects of the present invention are not impaired. As the other components contained in the thermosetting composition according to the present embodiment, for example, additives such as a reactive compound capable of reacting with the thermosetting compound, a thermoplastic resin (elastomer), a reaction initiator, a curing accelerator, a catalyst, a polymerization retarder, a polymerization inhibitor, a dispersant, a leveling agent, a silane coupling agent, an antifoaming agent, an antioxidant, a heat stabilizer, an antistatic agent, an ultraviolet absorber, a dye or a pigment, and a lubricant may be further contained.

The thermosetting composition according to the present embodiment may contain the reactive compound. The reactive compound is a compound different from the thermosetting compound, and examples thereof include a compound that reacts with the thermosetting compound. The reactive compound is not particularly limited, but examples thereof include styrene, styrene derivatives, acrylate compounds having an acryloyl group in the molecule, methacrylate compounds having a methacryloyl group in the molecule, vinyl compounds having a vinyl group in the molecule, maleimide compounds having a maleimide group in the molecule, modified maleimide compounds, alkenyl isocyanurate compounds, acenaphthylene compounds, cyanate ester compounds, and active ester compounds. The other reactive compound may be used singly or in combination of two or more kinds thereof.

Examples of the styrene derivatives include bromostyrene and dibromostyrene.

Examples of the acrylate compound include a polyfunctional acrylate compound having two or more acryloyl groups in the molecule, such as tricyclodecane dimethanol diacrylate.

Examples of the methacrylate compound include a polyfunctional methacrylate compound having two or more methacryloyl groups in the molecule, such as tricyclodecane dimethanol diacrylate.

Examples of the vinyl compound include a polyfunctional vinyl compound having two or more vinyl groups in the molecule, such as divinylbenzene and polybutadiene.

Examples of the maleimide compound include a monofunctional maleimide compound having one maleimide group in the molecule, and a polyfunctional maleimide compound having two or more maleimide groups in the molecule. Examples of the modified maleimide compound include a modified maleimide compound in which a part of the molecule is modified with an amine, a modified maleimide compound in which a part of the molecule is modified with silicone, and a modified maleimide compound in which a part of the molecule is modified an amine and silicone.

The alkenyl isocyanurate compound is only required to be a compound having an isocyanurate structure and an alkenyl group in the molecule, and examples thereof include a trialkenyl isocyanurate compound such as triallyl isocyanurate (TAIC).

The acenaphthylene compound is a compound having an acenaphthylene structure in the molecule. Examples of the acenaphthylene compound include acenaphthylene, alkylacenaphthylenes, halogenated acenaphthylenes, and phenylacenaphthylenes. Examples of the alkyl acenaphthylenes include 1-methyl acenaphthylene, 3-methyl acenaphthylene, 4-methyl acenaphthylene, 5-methyl acenaphthylene, 1-ethyl acenaphthylene, 3-ethyl acenaphthylene, 4-ethyl acenaphthylene, and 5-ethyl acenaphthylene. Examples of the halogenated acenaphthylenes include 1-chloroacenaphthylene, 3-chloroacenaphthylene, 4-chloroacenaphthylene, 5-chloroacenaphthylene, 1-bromoacenaphthylene, 3-bromoacenaphthylene, 4-bromoacenaphthylene, and 5-bromoacenaphthylene. Examples of the phenylacenaphthylenes include 1-phenylacenaphthylene, 3-phenylacenaphthylene, 4-phenylacenaphthylene, and 5-phenylaccnaphthylene. The acenaphthylene compound may be a monofunctional acenaphthylene compound having one acenaphthylene structure in the molecule as described above or may be a polyfunctional acenaphthylene compound having two or more acenaphthylene structures in the molecule.

The cyanate ester compound is a compound having a cyanato group in the molecule, and examples thereof include 2,2-bis(4-cyanatophenyl)propane, bis(3,5-dimethyl-4-cyanatophenyl)methane, and 2,2-bis(4-cyanatophenyl)ethane.

The active ester compound is a compound having an ester group exhibiting high reaction activity in the molecule, and examples thereof include a benzenecarboxylic acid active ester, a benzenedicarboxylic acid active ester, a benzenetricarboxylic acid active ester, a benzenetetracarboxylic acid active ester, a naphthalenecarboxylic acid active ester, a naphthalenedicarboxylic acid active ester, a naphthalenetricarboxylic acid active ester, a naphthalenetetracarboxylic acid active ester, a fluorenecarboxylic acid active ester, a fluorenedicarboxylic acid active ester, a fluorenetricarboxylic acid active ester, and a fluorenetetracarboxylic acid active ester.

As described above, the thermosetting composition according to the present embodiment may contain a reaction initiator. The curing reaction can proceed even though the thermosetting composition does not contain a reaction initiator. However, a reaction initiator may be added since there is a case where it is difficult to raise the temperature until curing proceeds depending on the process conditions. The reaction initiator is not particularly limited as long as it can promote the curing reaction of the thermosetting composition, and examples thereof include a peroxide and an organic azo compound. Examples of the peroxide include dicumyl peroxide, α,α′-bis(t-butylperoxy-m-isopropyl)benzene, 2,5-dimethyl-2,5-di(t-butylperoxy)-3-hexyne, and benzoyl peroxide. Examples of the organic azo compound include azobisisobutyronitrile. A metal carboxylate can be concurrently used if necessary. By doing so, the curing reaction can be further promoted. Among these, α,α′-bis(t-butylperoxy-m-isopropyl)benzene is preferably used. α,α′-Bis(t-butylperoxy-m-isopropyl)benzene has a relatively high reaction initiation temperature and thus can suppress the promotion of the curing reaction at the time point at which curing is not required, for example, at the time of prepreg drying, and can suppress a decrease in storage stability of the thermosetting composition. α,α′-Bis(t-butylperoxy-m-isopropyl)benzene exhibits low volatility, thus does not volatilize at the time of prepreg drying and storage, and exhibits favorable stability. The reaction initiators may be used singly or in combination of two or more kinds thereof.

As described above, the resin composition according to the present embodiment may contain an elastomer. Examples of the elastomer include a styrenic copolymer. Examples of the styrenic copolymer include a methylstyrene (ethylene/butylene) methylstyrene copolymer, a methylstyrene (ethylene-ethylene/propylene) methylstyrene copolymer, a styrene isoprene copolymer, a styrene isoprene styrene copolymer, a styrene (ethylene/butylene) styrene copolymer, a styrene (ethylene-ethylene/propylene) styrene copolymer, a styrene butadiene styrene copolymer, a styrene (butadiene/butylene) styrene copolymer, a styrene isobutylene styrene copolymer, and hydrogenated products of these copolymers. As the elastomer, those exemplified above may be used singly or in combination of two or more kinds thereof.

As described above, the thermosetting composition according to the present embodiment may contain a curing accelerator. The curing accelerator is not particularly limited as long as it can promote the curing reaction of the thermosetting composition. Specific examples of the curing accelerator include imidazoles and derivatives thereof, organophosphorus compounds, amines such as secondary amines and tertiary amines, quaternary ammonium salts, organoboron compounds, and metal soaps. Examples of the imidazoles include 2-ethyl-4-methylimidazole, 2-methylimidazole, 2-phenyl-4-methylimidazole, 2-phenylimidazole, and 1-benzyl-2-methylimidazole. Examples of the organophosphorus compounds include triphenylphosphine, diphenylphosphine, phenylphosphine, tributylphosphine, and trimethylphosphine. Examples of the amines include dimethylbenzylamine, triethylenediamine, triethanolamine, and 1,8-diaza-bicyclo(5,4,0)undecene-7 (DBU). Examples of the quaternary ammonium salts include tetrabutylammonium bromide. Examples of the organoboron compounds include tetraphenylboron salts such as 2-ethyl-4-methylimidazole-tetraphenylborate and tetra-substituted phosphonium/tetra-substituted borate such as tetraphenylphosphonium/ethyltriphenylborate. The metal soap refers to a fatty acid metal salt, and may be a linear fatty acid metal salt or a cyclic fatty acid metal salt. Specific examples of the metal soaps include C₆₋₁₀ linear aliphatic metal salts and cyclic aliphatic metal salts. More specific examples thereof include aliphatic metal salts formed from linear fatty acids such as stearic acid, lauric acid, ricinoleic acid, and octylic acid and cyclic fatty acids such as naphthenic acid and metals such as lithium, magnesium, calcium, barium, copper, and zinc. Examples thereof include zinc octylate. The curing accelerators may be used singly or in combination of two or more kinds thereof.

As described above, the thermosetting composition according to the present embodiment may contain a silane coupling agent. The silane coupling agent may be contained in the thermosetting composition or may be contained as a silane coupling agent covered on the inorganic filler contained in the thermosetting composition for surface treatment in advance. Among these, it is preferable that the silane coupling agent is contained as a silane coupling agent covered on the inorganic filler for surface treatment in advance, and it is more preferable that the silane coupling agent is contained as a silane coupling agent covered on the inorganic filler for surface treatment in advance and further is also contained in the thermosetting composition. In the case of a prepreg, the silane coupling agent may be contained in the prepreg as a silane coupling agent covered on the fibrous base material for surface treatment in advance. Examples of the silane coupling agent include those similar to the silane coupling agents used in the surface treatment of the inorganic filler described above.

As described above, the thermosetting composition according to the present embodiment may contain a flame retardant. The flame retardancy of a cured product of the thermosetting composition can be enhanced by containing a flame retardant. The flame retardant is not particularly limited. Specifically, in the field in which halogen-based flame retardants such as bromine-based flame retardants are used, for example, ethylenedipentabromobenzene, ethylenebistetrabromoimide, decabromodiphenyloxide, and tetradecabromodiphenoxybenzene that have a melting point of 300° C. or more, and a bromostyrenic compound that reacts with the polymerizable compound are preferable. It is considered that the elimination of halogen at a high temperature and the decrease in heat resistance can be suppressed by the use of a halogen-based flame retardant. There is a case where a flame retardant containing phosphorus (phosphorus-based flame retardant) is used in fields required to be halogen-free. The phosphorus-based flame retardant is not particularly limited, and examples thereof include a phosphate ester-based flame retardant, a phosphazene-based flame retardant, a bis(diphenylphosphine oxide)-based flame retardant, and a phosphinate-based flame retardant. Specific examples of the phosphate ester-based flame retardant include a condensed phosphate ester such as dixylenyl phosphate. Specific examples of the phosphazene-based flame retardant include phenoxyphosphazene. Specific examples of the bis(diphenylphosphine oxide)-based flame retardant include xylylenebis(diphenylphosphine oxide). Specific examples of the phosphinate-based flame retardant include metal phosphinates such as an aluminum dialkyl phosphinate. As the flame retardant, the respective flame retardants exemplified may be used singly or in combination of two or more kinds thereof.

The prepreg may contain a silane coupling agent. The silane coupling agent is not particularly limited. The method for adding the silane coupling agent is not limited as long as the silane coupling agent is contained in the prepreg. As the method for adding the silane coupling agent, for example, when the thermosetting composition is produced, the silane coupling agent may be added by adding an inorganic filler that is covered with the silane coupling agent for surface treatment in advance as described above, or the inorganic filler and the silane coupling agent may be added by an integral blending method. When the prepreg is manufactured, the silane coupling agent may be added to the prepreg by using a fibrous base material that is covered with the silane coupling agent for surface treatment in advance.

### (Varnish)

The thermosetting composition used in the present embodiment may be prepared in the form of a varnish. For example, the thermosetting composition may be prepared in the form of a varnish and used for the purpose of impregnating the fibrous base material with the thermosetting composition when a prepreg is manufactured. In other words, the thermosetting composition may be used as one (varnish) prepared in the form of a varnish. In the thermosetting composition used in the present embodiment, the thermosetting compound is dissolved in the varnish. Such a varnish-like composition (varnish) is prepared, for example, as follows.

First, the respective components which can be dissolved in an organic solvent are introduced into and dissolved in an organic solvent. At this time, heating may be performed if necessary. Thereafter, components, which are used if necessary but are not dissolved in the organic solvent, are added to and dispersed in the solution until a predetermined dispersion state is achieved using a ball mill, a bead mill, a planetary mixer, a roll mill or the like, whereby a varnish-like composition is prepared. The organic solvent used here is not particularly limited as long as it dissolves the polymer and the curing agent and does not inhibit the curing reaction. Specific examples thereof include toluene and methyl ethyl ketone (MEK).

### (Dielectric Properties of Prepreg)

In order to suppress loss due to increased resistance accompanying refinement of wiring, the insulating layer equipped in a wiring board is also required to be excellent in dielectric properties, such as a low relative dielectric constant and a low dielectric loss tangent. The prepreg is a prepreg, which affords a cured product that is not only excellent in heat resistance and processability but is also excellent in dielectric properties such as a low relative dielectric constant and a low dielectric loss tangent. Specifically, the relative dielectric constant of a cured product of the prepreg is preferably 2.3 to 3.5, more preferably 2.5 to 3.3. The dielectric loss tangent of a cured product of the prepreg is preferably 0.0025 or less, more preferably 0.002 or less. It is more preferable as the dielectric loss tangent of a cured product of the prepreg is lower, and the lower limit of the dielectric loss tangent is not particularly limited, but may be, for example, 0.0005 or more. When the relative dielectric constant and dielectric loss tangent of a cured product of the prepreg are within the above ranges, the low dielectric properties are excellent. It is preferable to adjust the composition of the thermosetting composition, for example, the content of the inorganic filler so that the relative dielectric constant and dielectric loss tangent of a cured product of the prepreg are within the above ranges. The relative dielectric constant and dielectric loss tangent here include the relative dielectric constant and dielectric loss tangent of a cured product of the prepreg at 10 GHz.

### (Resin Content in Prepreg)

The resin content in the prepreg is not particularly limited, but is, for example, preferably 40% to 90% by mass, more preferably 45% to 90% by mass, still more preferably 50% to 80% by mass. When the resin content is too low, it tends to be difficult to obtain low dielectric properties. When the resin content is too high, the coefficient of thermal expansion (CTE) tends to be high or the plate thickness accuracy tends to decrease. The resin content here is the ratio of the mass acquired by subtracting the mass of the fibrous base material from the mass of the prepreg to the mass of the prepreg [=(mass of prepreg−mass of fibrous base material)/mass of prepreg×100].

### (Thickness of Prepreg)

The thickness of the prepreg is not particularly limited, but is, for example, preferably 0.015 to 0.2 mm, more preferably 0.02 to 0.15 mm, still more preferably 0.03 to 0.13 mm. When the prepreg is too thin, a large number of prepregs are required in order to obtain the desired substrate thickness. When the prepreg is too thick, the resin content tends to be low and it tends to be difficult to obtain the desired low dielectric properties.

### (Manufacturing Method)

Next, a method for manufacturing the prepreg of the present embodiment will be described.

The method for manufacturing the prepreg is not particularly limited as long as the prepreg can be manufactured. Specifically, when the prepreg is manufactured, the thermosetting composition, which has been described above and is used in the present embodiment, is often prepared in the form of a varnish and used as a varnish as described above.

Examples of the method for manufacturing the prepreg 1 include a method in which the fibrous base material 3 is impregnated with the thermosetting composition 2, for example, the thermosetting composition 2 prepared in the form of a varnish, and then dried.

The fibrous base material 3 is impregnated with the thermosetting composition 2 by dipping, coating, and the like. If necessary, the impregnation can be repeated a plurality of times. At this time, it is also possible to finally adjust the composition and impregnated amount to the desired composition and impregnated amount by repeating impregnation using a plurality of thermosetting compositions having different compositions and concentrations.

The fibrous base material 3 impregnated with the thermosetting composition (varnish) 2 is heated under desired heating conditions, for example, at 80° C. or more and 180° C. or less for 1 minute or more and 10 minutes or less. By heating, the prepreg 1 before being cured (A-stage) or in a semi-cured state (B-stage) is obtained. By the heating, the organic solvent can be decreased or removed by being volatilized from the varnish.

### [Metal-Clad Laminate and Wiring Board]

By using the prepreg according to the present embodiment, a metal-clad laminate and a wiring board can be obtained as described below.

### (Metal-Clad Laminate)

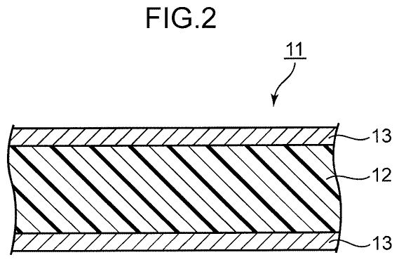

As illustrated in FIG. 2, a metal-clad laminate 11 according to the present embodiment includes an insulating layer 12 containing a cured product of the prepreg 1 illustrated in FIG. 1 and a metal foil 13 provided on the insulating layer 12. Examples of the metal-clad laminate 11 include a metal-clad laminate including an insulating layer 12 used by curing the prepreg 1 illustrated in FIG. 1 and a metal foil 13 laminated together with the insulating layer 12. The insulating layer 12 may be composed of a cured product of the prepreg 1. The thickness of the metal foil 13 varies depending on the performance and the like to be required for the finally obtained wiring board and is not particularly limited. The thickness of the metal foil 13 can be appropriately set depending on the desired purpose and is preferably, for example, 0.2 to 70 μm. Examples of the metal foil 13 include a copper foil and an aluminum foil, and the metal foil 13 may be a copper foil with carrier which includes a release layer and a carrier for the improvement in handleability in a case where the metal foil is thin. FIG. 2 is a schematic sectional view illustrating an example of the metal-clad laminate 11 according to an embodiment of the present invention.

The method for manufacturing the metal-clad laminate 11 is not particularly limited as long as the metal-clad laminate 11 can be manufactured using the prepreg 1. Examples of the method for fabricating the metal-clad laminate 11 using the prepreg 1 specifically include a method in which a double-sided metal foil-clad or single-sided metal foil-clad laminate 11 is fabricated by stacking one sheet or a plurality of sheets of prepreg 1, further stacking the metal foil 13 such as a copper foil on both or one of upper and lower surfaces of the prepreg 1, and laminating and integrating the metal foils 13 and prepregs 1 by heating and pressing. In other words, the metal-clad laminate 11 is obtained by laminating the metal foil 13 on the prepreg 1 and then performing heating and pressing. The heating and pressing conditions can be appropriately set depending on the thickness of the metal-clad laminate 11, the kind of the thermosetting composition contained in the prepreg 1, and the like. For example, it is possible to set the temperature to 170 to 230° C., the pressure to 0.5 to 5 MPa, and the time to 60 to 150 minutes.

### (Wiring Board)

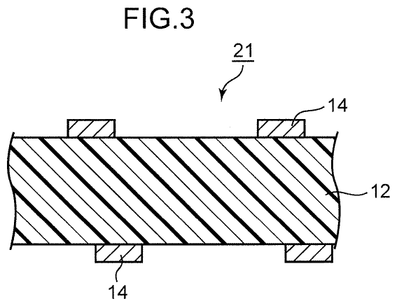

As illustrated in FIG. 3, a wiring board 21 according to the present embodiment includes an insulating layer 12 containing a cured product of the prepreg 1 illustrated in FIG. 1 and a wiring 14 provided on the insulating layer 12. Examples of the wiring board 21 include a wiring board formed of an insulating layer 12 obtained by curing the prepreg 1 illustrated in FIG. 1 and wiring 14 which is laminated together with the insulating layer 12 and is formed by partially removing the metal foil 13. In other words, the wiring board 21 includes the insulating layer 12 containing a cured product of the prepreg 1 and the wiring 14 bonded to the insulating layer 12. The insulating layer 12 may be composed of a cured product of the prepreg 1. FIG. 3 is a schematic sectional view illustrating an example of the wiring board 21 according to an embodiment of the present invention.

The method for manufacturing the wiring board 21 is not particularly limited as long as the wiring board 21 can be manufactured using the prepreg 1. Examples of the method for fabricating the wiring board 21 using the prepreg 1 include a method in which the wiring board 21, in which a wiring is provided as a circuit on the surface of the insulating layer 12, is fabricated by forming the wiring through etching and the like of the metal foil 13 on the surface of the metal-clad laminate 11 fabricated in the manner described above. In other words, the wiring board 21 is obtained by partially removing the metal foil 13 on the surface of the metal-clad laminate 11 and thus forming a circuit. Examples of the method for forming a circuit include circuit formation by a semi-additive process (SAP) or a modified semi-additive process (MSAP) in addition to the method described above.

When cured, the prepreg according to the present embodiment becomes a cured product that is excellent in heat resistance and processability while maintaining excellent dielectric properties. For this reason, the metal-clad laminate and wiring board obtained by using this prepreg are a metal-clad laminate and a wiring board, which include an insulating layer that is excellent in heat resistance and processability while maintaining excellent dielectric properties, respectively. The wiring board can be manufactured when the metal-clad laminate is used.

The present specification discloses technologies in various aspects as described above, and the main technologies among these are summarized below.

A prepreg according to a first aspect of the present invention is a prepreg including a thermosetting composition containing a thermosetting compound and an inorganic filler or a semi-cured product of the thermosetting composition; and a fibrous base material containing a liquid crystal polymer fiber, in which the thermosetting compound includes at least one selected from the group consisting of a polyphenylene ether compound having a carbon-carbon unsaturated double bond in a molecule, a hydrocarbon-based compound having a carbon-carbon unsaturated double bond in a molecule, and a thermosetting compound having a fluorine atom in a molecule, the inorganic filler contains at least one selected from the group consisting of silica, quartz glass, and magnesium oxide as a material, a content of the inorganic filler is 65 parts by mass or more with respect to 100 parts by mass of the thermosetting compound, and a ratio of a total amount of a group represented by the following Formula (3), a group represented by the following Formula (4), and a group represented by the following Formula (5) to a total amount of a group represented by the following Formula (1) and a group represented by the following Formula (2), as measured by X-ray photoelectron spectroscopy, is 0.3 or more and less than 0.55 on a surface of the fibrous base material.

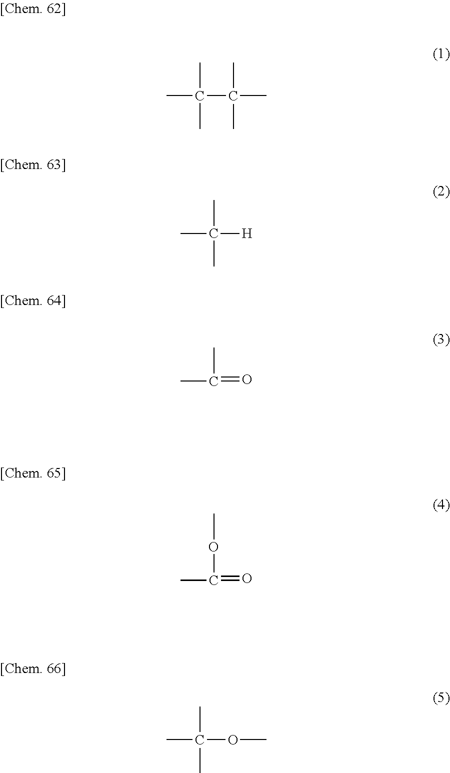

A prepreg according to a second aspect of the present invention is the prepreg according to the first aspect of the present invention, in which the fibrous base material includes a fibrous base material having a surface subjected to plasma treatment.

A prepreg according to a third aspect of the present invention is the prepreg according to the first or second aspect of the present invention, in which the fibrous base material includes a fibrous base material having a surface subjected to plasma treatment including at least one selected from the group consisting of oxygen gas plasma treatment, oxygen and carbon tetrafluoride mixed gas plasma treatment, and argon, hydrogen and nitrogen mixed gas plasma treatment.

A metal-clad laminate according to a fourth aspect of the present invention is a metal-clad laminate including an insulating layer containing a cured product of the prepreg according to any one of the first to third aspects of the present invention; and a metal foil.

A metal-clad laminate according to a fifth aspect of the present invention is a wiring board including an insulating layer containing a cured product of the prepreg according to any one of the first to third aspects of the present invention; and a wiring.

According to the present invention, it is possible to provide a prepreg, which affords a cured product that is excellent in heat resistance and processability while maintaining excellent dielectric properties. According to the present invention, it is possible to provide a metal-clad laminate and a wiring board, which are obtained by using the prepreg.

Hereinafter, the present invention will be described more specifically with reference to examples, but the scope of the present invention is not limited thereto.

### EXAMPLES

### Examples 1 to 8 and Comparative Examples 1 and 2

The respective components used when a prepreg is fabricated in the present Examples will be described.

### (Thermosetting Compound)

Hydrocarbon-based compound: A polyfunctional vinyl aromatic copolymer obtained by conducting a reaction as follows.

Into a 5.0 L reactor, 3.0 mole (390.6 g) of divinylbenzene, 1.8 mole (229.4 g) of ethylvinylbenzene, 10.2 mole (1066.3 g) of styrene and 15.0 mole (1532.0 g) of n-propyl acetate were charged, 600 mmol of boron trifluoride diethyl ether complex was added at 70° C., and the reaction was conducted for 4 hours. After that, an aqueous sodium bicarbonate solution was added to the obtained reaction mixture in order to stop the reaction, and then the oil layer was washed three times with pure water and volatilized under reduced pressure at 60° C. to recover the solid (polymer). The obtained solid was weighed to find that 896.7 g was obtained.

The structure of the obtained solid (polymer) was measured by ¹³C-NMR and ¹H-NMR analysis using a nuclear magnetic resonance spectrometer, Model JNM-LA600 manufactured by JEOL Ltd. Chloroform-d₁ was used as the solvent and the resonance line of tetramethylsilane was used as the internal standard. In addition to the ¹³C-NMR and ¹H-NMR measurement results, the amount of a specific structural unit introduced was calculated from the data on the total amount of the respective structural units introduced into the copolymer acquired by gas chromatographic (GC) analysis, and the amount of the pendant vinyl group unit contained in the polyfunctional vinyl aromatic copolymer was calculated from the amount of the specific structural unit introduced at the terminal and the number average molecular weight acquired by the GPC measurement.

The obtained solid was subjected to ¹³C-NMR and ¹H-NMR analysis as described above to observe resonance lines derived from each monomer unit. Based on the results of NMR measurement and the results of GC analysis, it was found that this solid was the polyfunctional vinyl aromatic copolymer. The structural units of this polyfunctional vinyl aromatic copolymer were then calculated as follows based on the results of NMR measurement and the results of GC analysis. The structural unit derived from divinylbenzene was 30.4 mol % (33.1% by mass), the structural unit derived from styrene was 57.4 mol % (52.7% by mass), the structural unit derived from ethylvinylbenzene was 12.2 mol % (14.2% by mass), and the structural unit having a residual vinyl group, which was derived from divinylbenzene, was 23.9 mol % (25.9% by mass).

The molecular weight and molecular weight distribution of the obtained solid (polyfunctional vinyl aromatic copolymer) were measured using tetrahydrofuran as a solvent and a calibration curve created using monodisperse polystyrene at a flow rate of 1.0 ml/min and a column temperature of 38° C. using GPC (HLC-8120GPC manufactured by Tosoh Corporation). As a result, the obtained solid had a number average molecular weight Mn of 2980, a weight average molecular weight Mw of 41300, and Mw/Mn of 13.9.

Polyphenylene ether compound: A polyphenylene ether compound having a vinylbenzyl group (ethenylbenzyl group) at the terminal (a modified polyphenylene ether compound obtained by reacting polyphenylene ether with chloromethylstyrene).

Specifically, this is a modified polyphenylene ether compound obtained by conducting a reaction as follows.

First, 200 g of polyphenylene ether (SA90 manufactured by SABIC Innovative Plastics Co., Ltd., number of terminal hydroxyl groups: 2, weight average molecular weight Mw 1700), 30 g of a mixture containing p-chloromethylstyrene and m-chloromethylstyrene at a mass ratio of 50:50 (chloromethylstyrene: CMS manufactured by Tokyo Chemical Industry Co., Ltd.), 1.227 g of tetra-n-butylammonium bromide as a phase transfer catalyst, and 400 g of toluene were introduced into a 1-liter three-necked flask equipped with a temperature controller, a stirrer, cooling equipment, and a dropping funnel and stirred. Then, the mixture was stirred until polyphenylene ether, chloromethylstyrene, and tetra-n-butylammonium bromide were dissolved in toluene. At that time, the mixture was gradually heated until the liquid temperature finally reached 75° C. Then, an aqueous sodium hydroxide solution (20 g of sodium hydroxide/20 g of water) as an alkali metal hydroxide was added dropwise to the solution over 20 minutes. Thereafter, the mixture was further stirred at 75° C. for 4 hours. Next, the resultant in the flask was neutralized with hydrochloric acid at 10% by mass and then a large amount of methanol was added into the flask. By doing so, a precipitate was generated in the liquid in the flask. In other words, the product contained in the reaction solution in the flask was reprecipitated. Then, this precipitate was taken by filtration and washed three times with a liquid mixture of methanol and water at a mass ratio of 80:20, and then dried at 80° C. under reduced pressure for 3 hours.

The obtained solid was analyzed by ¹H-NMR (400 MHz, CDCl₃, TMS). As a result of NMR measurement, a peak attributed to a vinylbenzyl group (ethenylbenzyl group) was observed at 5 to 7 ppm. This made it possible to confirm that the obtained solid was a modified polyphenylene ether compound having a vinylbenzyl group (ethenylbenzyl group) as the substituent at the molecular terminal in the molecule. Specifically, the obtained solid was confirmed to be ethenylbenzylated polyphenylene ether. This modified polyphenylene ether compound obtained was a modified polyphenylene ether compound represented by Formula (52), where Y was a dimethylmethylene group (a group represented by Formula (50), where R₃₃ and R₃₄ were a methyl group), Ar was a phenylene group, R₁ to R₃ were a hydrogen atom, and p was 1.

The number of terminal functional groups in the modified polyphenylene ether was measured as follows.

First, the modified polyphenylene ether was accurately weighed. The weight at that time is defined as X (mg). Thereafter, this modified polyphenylene ether weighed was dissolved in 25 mL of methylene chloride, 100 μL of an ethanol solution of tetraethylammonium hydroxide (TEAH) at 10% by mass (TEAH: ethanol (volume ratio)=15:85) was added to the solution, and then the absorbance (Abs) of this mixture at 318 nm was measured using a UV spectrophotometer (UV-1600 manufactured by Shimadzu Corporation). Then, the number of terminal hydroxyl groups in the modified polyphenylene ether was calculated from the measurement results using the following equation.

$$Residual OH amount ( µmol / g ) = [ ( 25 \times Abs ) / ( ε \times OPL \times X ) ] \times {10}^{6}$$

Here, ε denotes the extinction coefficient and is 4700 L/mol·cm. OPL denotes the cell optical path length and is 1 cm.

Since the calculated residual OH amount (the number of terminal hydroxyl groups) in the modified polyphenylene ether is almost zero, it was found that the hydroxyl groups in the polyphenylene ether before being modified are almost modified. From this fact, it was found that the number of terminal hydroxyl groups decreased from the number of terminal hydroxyl groups in polyphenylene ether before being modified was the number of terminal hydroxyl groups in polyphenylene ether before being modified. In other words, it was found that the number of terminal hydroxyl groups in polyphenylene ether before being modified was the number of terminal functional groups in the modified polyphenylene ether. In other words, the number of terminal functional groups was 2.

In addition, an intrinsic viscosity (IV) of the modified polyphenylene ether was measured in methylene chloride at 25° C. Specifically, the intrinsic viscosity (IV) of the modified polyphenylene ether was measured in a methylene chloride solution (liquid temperature: 25° C.) of the modified polyphenylene ether at 0.18 g/45 ml using a viscometer (AVS500 Visco System manufactured by SCHOTT Instruments GmbH). As a result, the intrinsic viscosity (IV) of the modified polyphenylene ether was 0.086 dl/g.

The molecular weight distribution of the modified polyphenylene ether was measured by GPC. Moreover, the weight average molecular weight (Mw) was calculated from the obtained molecular weight distribution. As a result, Mw was 1,900.

Fluorine-containing thermosetting compound: A fluororesin represented by Formula (56), where q is 1, L is a cyclohexyl group, R₃₉ is a fluorine atom, and R₄₀ is a fluorine atom.

Specifically, the fluorine-containing thermosetting compound is a fluororesin obtained by conducting a reaction as follows.

A glass reaction vessel was charged with 0.805 g (3.0 mmol) of 1,1-bis(4-hydroxyphenyl)cyclohexane (bisphenol Z) and 0.912 g (6.6 mmol) of potassium carbonate. The inside of the glass reaction vessel was evacuated to vacuum and then purged with nitrogen. Next, 10 mL of dimethylacetamide (DMAc) was added to the glass reaction vessel. The reaction mixture was heated to 150° C. while stirring was performed and stirred for 3 hours. After heating was completed, the reaction mixture was cooled to room temperature. Next, 0.802 g (2.4 mmol) of decafluorobiphenyl was added to the reaction mixture. The reaction mixture was heated to 70° C. while stirring was performed and stirred for 4 hours. Next, the reaction mixture was protected from light and 0.17 mL (0.233 g, 1.2 mmol) of 2,3,4,5,6-pentafluorostyrene was added. Stirring was continuously performed at a temperature of 70° C. for 15 hours. After stirring was completed, the reaction mixture was cooled to room temperature. The reaction mixture was then poured into 0.5 L of pure water. The reaction mixture was subjected to suction filtration, and the obtained solid substance was washed with pure water and methanol. The washed solid substance was dried under reduced pressure to obtain about 1.14 g of fluororesin.

### (Inorganic Filler)

Silica: Silica filler (EQ-2410-SBG manufactured by Third Age Technology Co., Ltd.)
Quartz glass: Quartz glass filler (PQSF manufactured by Jiangsu Pacific Quartz Co., Ltd.)
Magnesium oxide: Magnesium oxide filler (RF-10CS manufactured by Ube Material Industries, Ltd.)

### (Fibrous Base Material)

Fibrous base material A: A fibrous base material obtained by subjecting a fibrous base material containing liquid crystal polymer fibers (HT series manufactured by Kuraray Co., Ltd.) to oxygen gas plasma treatment under the plasma treatment conditions presented in Table 1 (oxygen gas was used as the raw material gas, the plasma radiation dose was 0.5 W/cm² in terms of watt density, and the plasma treatment time was 10 minutes). The ratio (b/a) of this fibrous base material A was measured by the method described below, and was found to be 0.32, as presented in Table 1.

The ratio (b/a) of the fibrous base material was measured as follows. First, surface X-ray analysis was performed on the surface of the fibrous base material using an X-ray photoelectron spectroscopic analyzer (XPS, PHI 5000 Versaprobe manufactured by ULVAC-PHI, Inc.). The surface of the fibrous base material was irradiated with X-rays under the following conditions in a vacuum from a direction perpendicular to the surface, the height for irradiation was adjusted, and this surface X-ray analysis was performed at a position where photoelectrons emitted by the sample ionization could be detected with the strongest intensity.

### X-Ray Used: Monochrome Al-Kα Ray

X-ray beam diameter: About 100 μmφ (25 W, 15 kV)
Analysis area: About 100 μmφ

The spectrum acquired by the surface X-ray analysis was analyzed using analysis software equipped in the apparatus (quantitative conversion using relative sensitivity factors built into the analysis software, and the like), thereby measuring the ratio (b/a).

Fibrous base material B: a fibrous base material obtained by subjecting a fibrous base material containing liquid crystal polymer fibers (HT series manufactured by Kuraray Co., Ltd.) to oxygen gas plasma treatment under the plasma treatment conditions presented in Table 1 (oxygen gas was used as the raw material gas, the plasma radiation dose was 0.5 W/cm² in terms of watt density, and the plasma treatment time was 20 minutes). The ratio (b/a) of this fibrous base material B was measured by the method, and was found to be 0.44, as presented in Table 1.

Fibrous base material C: a fibrous base material obtained by subjecting a fibrous base material containing liquid crystal polymer fibers (HT series manufactured by Kuraray Co., Ltd.) to oxygen gas plasma treatment under the plasma treatment conditions presented in Table 1 (oxygen gas was used as the raw material gas, the plasma radiation dose was 0.5 W/cm² in terms of watt density, and the plasma treatment time was 5 minutes). The ratio (b/a) of this fibrous base material C was measured by the method described below, and was found to be 0.21, as presented in Table 1.

### [Preparation Method]

First, the component (thermosetting compound) other than the inorganic filler was added to and mixed in toluene so that the solid concentration was 30% by mass. The mixture was stirred for 60 minutes. Thereafter, the inorganic filler was added to the obtained liquid so that the composition (parts by mass) presented in Table 1 was obtained, and dispersed in the liquid using a bead mill. By doing so, a varnish-like composition (varnish) was obtained.

Next, the obtained varnish was impregnated into a fibrous base material presented in Table 1, and then heating and drying was performed at 100° C. to 160° C. for about 2 to 8 minutes, thereby obtaining a prepreg. At that time, the thickness of the prepreg after curing was adjusted to be about 125 μm (the content of the thermosetting compound was about 74% by mass).

### (Evaluation Substrate)

Then, copper foil having a thickness of 18 μm (ultra-low roughness electrolytic copper foil CF-T4X-SV manufactured by FUKUDA METAL FOIL & POWDER CO., LTD.) was disposed on both sides of each prepreg obtained to obtain a body to be pressed, and the body to be pressed was heated and pressed at a temperature of 220° C. and a pressure of 2 MPa for 2 hours, thereby obtaining a copper foil-clad laminate (metal-clad laminate) having a thickness of about 0.16 mm and having copper foil pasted to both surfaces. This obtained copper foil-clad laminate was designated as the evaluation substrate.

The evaluation substrates fabricated as described above were evaluated by the methods described below.

### [Dielectric Properties: Dielectric Loss Tangent (Df)]

The copper foil was removed from the evaluation substrate by etching. The substrate thus obtained was used as a test piece, and the relative dielectric constant and dielectric loss tangent at 10 GHz were measured by the cavity resonator perturbation method. Specifically, the dielectric loss tangent (Df) of the test piece at 10 GHz was measured using a network analyzer (N5230A manufactured by Agilent Technologies, Inc.).

### [Heat Resistance (Oven Heat Resistance)]

The evaluation substrate was left for 1 hour in a dryer set at a predetermined temperature, and the presence or absence of blistering on the evaluation substrate after being left was visually observed. The lowest temperature at which blistering was observed was used as the evaluation criterion for this heat resistance. In Table 1, this lowest temperature is referred to as the blistering temperature. Heat resistance was evaluated as “pass” in a case where blistering was not observed at 260° C., and as “failure” in a case where blistering was observed at 260° C. In a case where blistering is observed at 260° C., the blistering temperature is indicated as “-”.

### [Storage Modulus]

The evaluation substrate was cut to have a size of 10 mm×40 mm and attached to a dynamic viscoelasticity analyzer (DMS6100 manufactured by Seiko Instruments Inc.). The test was conducted at a strain amplitude of 10 μm, a frequency of 10 Hz (sine wave), and a rate of temperature increase of 5° C./min, and the storage modulus (MPa) at 40° C. was measured.

### [Thermal Expandability]

An unclad substrate obtained by removing the copper foil from the evaluation substrate by etching was cut to have a length of 25 mm and a width of 5 mm. This cut unclad substrate was used as a test piece, and this test piece was heated at 50° C. for 2 hours. The test piece was then heated at 260° C. for 2 hours. At that time, the distance between two predetermined points on the test piece in the warp direction of the fibrous base material was measured after heating at 50° C. and after heating at 260° C. The ratio (%) of the value acquired by subtracting the length after heating at 260 (260° C. length) from the length after heating at 50° C. (50° C. length) to the 50° C. length [(260° C. length−50° C. length)/50° C. length×100] was calculated, and this ratio (rate of dimensional change) (%) was used as the evaluation criterion for thermal expandability.

### [Processability]

The evaluation substrate was cut, and the end faces obtained by the cutting were observed using a scanning electron microscope (S-3000N manufactured by Hitachi High-Tech Fielding Corporation). As a result, processability was evaluated as “pass” when peeling of the copper foil was not observed, and as “failure” when peeling of the copper foil was observed. Processability was evaluated based on the presence or absence of such peeling of the copper foil on the end faces after cutting.

The results of each evaluation are presented in Table 1.

TABLE 1

| | | | Example | | | | |
|---|---|---|---|---|---|---|---|
| | | | 1 | 2 | 3 | 4 | 5 |
| Ther- | Composition | Hydrocarbon-based | 100 | 100 | 100 | 100 | — |
| mosetting | (parts by | compound | | | | | |
| composition | mass) | Polyphenylene | — | — | — | — | 100 |
| | | ether compound | | | | | |
| | | Fluorine-containing | — | — | — | — | — |
| | | thermosetting | | | | | |
| | | compound | | | | | |
| | | Silica | 130 | 130 | 80 | 100 | 130 |
| | | Quartz glass | — | — | — | — | — |
| | | Magnesium oxide | — | — | — | — | — |
| Fibrous | Fibrous base material | | A | B | B | B | B |
| base | Plasma | Kind of gas | O₂ | O₂ | O₂ | O₂ | O₂ |
| material | treatment | Watt density | 0.5 | 0.5 | 0.5 | 0.5 | 0.5 |
| | conditions | (W/cm²) | | | | | |
| | | Treatment | 10 | 20 | 20 | 20 | 20 |
| | | time (min) | | | | | |
| | Ratio (b/a) | | 0.32 | 0.44 | 0.44 | 0.44 | 0.44 |
| Evaluation | Heat | Blistering | 300 | 300 | 260 | 280 | 260 |
| | resistance | temperature (° C.) | | | | | |
| | | Evaluation | Pass | Pass | Pass | Pass | Pass |
| | Dielectric loss tangent Df | | 0.0011 | 0.0011 | 0.0012 | 0.0012 | 0.0022 |
| | Storage modulus (GPa) | | 5.8E+09 | 5.7E+09 | 5.0E+09 | 5.2E+09 | 5.5E+09 |
| | Thermal expandability (%) | | 0.48 | 0.49 | 0.64 | 0.55 | 0.47 |
| | Processability | | Pass | Pass | Pass | Pass | Pass |
| | | | Example | | | Comparative Example | |
| | | | 6 | 7 | 8 | 1 | 2 |
| Ther- | Composition | Hydrocarbon-based | 100 | 100 | | 100 | 100 |
| mosetting | (parts by | compound | | | | | |
| composition | mass) | Polyphenylene | — | — | — | — | — |
| | | ether compound | | | | | |
| | | Fluorine-containing | — | — | 100 | — | — |
| | | thermosetting | | | | | |
| | | compound | | | | | |
| | | Silica | — | — | 130 | 80 | 60 |
| | | Quartz glass | 130 | — | — | — | — |
| | | Magnesium oxide | — | 130 | — | — | — |
| Fibrous | Fibrous base material | | B | B | B | C | B |
| base | Plasma | Kind of gas | O₂ | O₂ | O₂ | O₂ | O₂ |
| material | treatment | Watt density | 0.5 | 0.5 | 0.5 | 0.5 | 0.5 |
| | conditions | (W/cm²) | | | | | |
| | | Treatment | 20 | 20 | 20 | 5 | 20 |
| | | time (min) | | | | | |
| | Ratio (b/a) | | 0.44 | 0.44 | 0.44 | 0.21 | 0.44 |
| Evaluation | Heat | Blistering | 300 | 290 | 280 | — | — |
| | resistance | temperature (° C.) | | | | | |
| | | Evaluation | Pass | Pass | Pass | Failure | Failure |

| | | | | | |
|---|---|---|---|---|---|
| Dielectric loss tangent Df | 0.0009 | 0.0010 | 0.0020 | 0.0012 | 0.0012 |
| Storage modulus (GPa) | 5.9E+09 | 6.1E+09 | 5.7E+09 | 5.0E+09 | 4.8E+09 |
| Thermal expandability (%) | 0.39 | 0.45 | 0.41 | 0.66 | 0.71 |
| Processability | Pass | Pass | Pass | Pass | Failure |

From Table 1, it was found that the prepregs (Examples 1 to 8), which include a thermosetting composition containing an inorganic filler at 65 parts by mass or more with respect to 100 parts by mass of a thermosetting compound, or a semi-cured product of the thermosetting composition, and a liquid crystal polymer fiber; and a fibrous base material having the ratio (b/a) of 0.3 or more and less than 0.55, were superior in heat resistance and processability to the other cases (Comparative Examples 1 and 2). Hence, it was found that the prepregs according to Examples 1 to 8 were excellent in heat resistance and processability while maintaining excellent dielectric properties. Specifically, the prepregs according to Examples 1 to 8 were not only excellent in processability, but also exhibited higher heat resistance than the prepreg (Comparative Example 1) including a fibrous base material having the ratio (b/a) of less than 0.3. The prepregs according to Examples 1 to 8 were superior in heat resistance and processability to the prepreg (Comparative Example 2) in which the content of the inorganic filler in the thermosetting composition was less than 65 parts by mass. With regard to the processability, from the storage modulus and thermal expandability presented in Table 1, it can be presumed that the processability is excellent when the storage modulus is high and the thermal expandability (rate of dimensional change due to thermal expansion) is low.

This application is based on Japanese Patent Application No. 2023-055776 filed on Mar. 30, 2023, the contents of which are included in the present application.

In order to express the present invention, the present invention has been described above appropriately and sufficiently through the embodiments. However, it should be recognized by those skilled in the art that changes and/or improvements of the above-described embodiments can be readily made. Accordingly, changes or improvements made by those skilled in the art shall be construed as being included in the scope of the claims unless otherwise the changes or improvements are at the level which departs from the scope of the appended claims.

### INDUSTRIAL APPLICABILITY

According to the present invention, a prepreg is provided, which affords a cured product that is excellent in heat resistance and processability while maintaining excellent dielectric properties. According to the present invention, a metal-clad laminate and a wiring board, which are obtained by using the prepreg, are provided.

1. A prepreg comprising:
a thermosetting composition containing a thermosetting compound and an inorganic filler or a semi-cured product of the thermosetting composition; and
a fibrous base material containing a liquid crystal polymer fiber,
wherein the thermosetting compound includes at least one selected from the group consisting of a polyphenylene ether compound having a carbon-carbon unsaturated double bond in a molecule, a hydrocarbon-based compound having a carbon-carbon unsaturated double bond in a molecule, and a thermosetting compound having a fluorine atom in a molecule,
the inorganic filler contains at least one selected from the group consisting of silica, quartz glass, and magnesium oxide as a material,
a content of the inorganic filler is 65 parts by mass or more with respect to 100 parts by mass of the thermosetting compound, and
a ratio of a total amount of a group represented by the following Formula (3), a group represented by the following Formula (4), and a group represented by the following Formula (5) to a total amount of a group represented by the following Formula (1) and a group represented by the following Formula (2), as measured by X-ray photoelectron spectroscopy, is 0.3 or more and less than 0.55 on a surface of the fibrous base material.

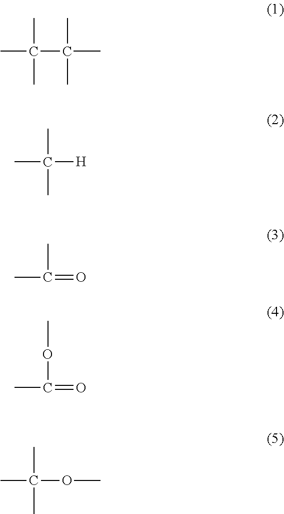

2. The prepreg according to claim 1, wherein the fibrous base material includes a fibrous base material having a surface subjected to plasma treatment.

3. The prepreg according to claim 1, wherein the fibrous base material includes a fibrous base material having a surface subjected to plasma treatment including at least one selected from the group consisting of oxygen gas plasma treatment, oxygen and carbon tetrafluoride mixed gas plasma treatment, and argon, hydrogen and nitrogen mixed gas plasma treatment.

4. A metal-clad laminate comprising:
an insulating layer containing a cured product of the prepreg according to claim 1; and
a metal foil.

5. A wiring board comprising:
an insulating layer containing a cured product of the prepreg according to claim 1; and
a wiring.
